(19) United States
(12) Patent Application Publication
(10) Pub. No.: US 2022/0059562 A1
(43) Pub. Date: Feb. 24, 2022

(54) SEMICONDUCTOR MEMORY DEVICE

(71) Applicant: Kioxia Corporation, Tokyo (JP)

(72) Inventor: Takashi YAMANE, Yokkaichi (JP)

(73) Assignee: Kioxia Corporation, Tokyo (JP)

(21) Appl. No.: 17/190,477

(22) Filed: Mar. 3, 2021

(30) Foreign Application Priority Data
Aug. 24, 2020 (JP) 2020-140651

(51) Int. Cl. H01L 27/11582; H01L 27/11565; H01L 27/1157; H01L 29/423; H01L 21/28

(52) U.S. Cl. CPC H01L 27/11582; H01L 27/11565; H01L 29/40117; H01L 29/4234; H01L 27/1157

(57) ABSTRACT

A semiconductor memory device according to one embodiment includes: substrate; first conductive layer separated from the substrate; and memory structure having an outer peripheral surface surrounded by the first conductive layer, wherein the memory structure includes: first insulating layer; n (n is a natural number of three or more) first semiconductor layers disposed between the first conductive layer and the first insulating layer, the n first semiconductor layers; and gate insulating film disposed between the first conductive layer and the n first semiconductor layers, and when an equilateral n-polygon passes through points on an outer peripheral surface of the first insulating layer and is circumscribed to the first insulating layer, the points have a shortest distance to the first conductive layer, and a range of the equilateral n-polygon is defined as a first range, the n first semiconductor layers are disposed inside the first range.

### CROSS-REFERENCE TO RELATED APPLICATIONS

This application is based upon and claims the benefit of Japanese Patent Application No. 2020-140651, filed on Aug. 24, 2020, the entire contents of which are incorporated herein by reference.

### BACKGROUND

### Field

Embodiments described herein relate generally to a semiconductor memory device.

### Description of the Related Art

There has been known a semiconductor memory device that includes a substrate, a plurality of gate electrodes stacked in a direction intersecting with a surface of the substrate, a semiconductor layer opposing the plurality of gate electrodes, and a gate insulating layer disposed between the gate electrodes and the semiconductor layer.

### BRIEF DESCRIPTION OF THE DRAWINGS

FIG. 1 is a schematic plan view illustrating a part of a configuration of a semiconductor memory device according to a first embodiment;

FIG. 2 is a schematic X-Y cross-sectional view illustrating a part of the configuration of the semiconductor memory device;

FIG. 3 is a schematic X-Y cross-sectional view illustrating a part of the configuration of the semiconductor memory device;

FIG. 4 is a schematic X-Y cross-sectional view illustrating a part of the configuration of the semiconductor memory device;

FIG. 5 is a schematic X-Y cross-sectional view illustrating a part of the configuration of the semiconductor memory device;

FIG. 6 is a schematic Y-Z cross-sectional view illustrating a part of the configuration of the semiconductor memory device;

FIG. 7 is a schematic Y-Z cross-sectional view for describing a method for manufacturing a semiconductor memory device according to the first embodiment;

FIG. 8 is a schematic Y-Z cross-sectional view for describing the manufacturing method;

FIG. 9 is a schematic X-Y cross-sectional view for describing the manufacturing method;

FIG. 10 is a schematic Y-Z cross-sectional view for describing the manufacturing method;

FIG. 11 is a schematic Y-Z cross-sectional view for describing the manufacturing method;

FIG. 12 is a schematic Y-Z cross-sectional view for describing the manufacturing method;

FIG. 13 is a schematic Y-Z cross-sectional view for describing the manufacturing method;

FIG. 14 is a schematic Y-Z cross-sectional view for describing the manufacturing method;

FIG. 15 is a schematic X-Y cross-sectional view for describing the manufacturing method;

FIG. 16 is a schematic Y-Z cross-sectional view for describing the manufacturing method;

FIG. 17 is a schematic X-Y cross-sectional view for describing the manufacturing method;

FIG. 18 is a schematic Y-Z cross-sectional view for describing the manufacturing method;

FIG. 19 is a schematic Y-Z cross-sectional view for describing the manufacturing method;

FIG. 20 is a schematic Y-Z cross-sectional view for describing the manufacturing method;

FIG. 21 is a schematic X-Y cross-sectional view for describing the manufacturing method;

FIG. 22 is a schematic Y-Z cross-sectional view for describing the manufacturing method;

FIG. 23 is a schematic Y-Z cross-sectional view for describing the manufacturing method;

FIG. 24 is a schematic X-Y cross-sectional view for describing the manufacturing method;

FIG. 25 is a schematic Y-Z cross-sectional view for describing the manufacturing method;

FIG. 26 is a schematic X-Y cross-sectional view for describing the manufacturing method;

FIG. 27 is a schematic Y-Z cross-sectional view for describing the manufacturing method;

FIG. 28 is a schematic X-Y cross-sectional view illustrating a part of a configuration of a semiconductor memory device according to a comparative example;

FIG. 29 is a schematic Y-Z cross-sectional view for describing a method for manufacturing the semiconductor memory device according to the comparative example;

FIG. 30 is a schematic X-Y cross-sectional view for describing the manufacturing method;

FIG. 31 is a schematic X-Y cross-sectional view for describing the manufacturing method;

FIG. 32 is a schematic X-Y cross-sectional view for describing the manufacturing method;

FIG. 33 is a schematic X-Y cross-sectional view illustrating apart of a configuration of a semiconductor memory device according to a second embodiment;

FIG. 34 is a schematic X-Y cross-sectional view for describing a method for manufacturing the semiconductor memory device according to the second embodiment;

FIG. 35 is a schematic X-Y cross-sectional view for describing the manufacturing method of the semiconductor memory device;

FIG. 36 is a schematic X-Y cross-sectional view illustrating a part of a configuration of a semiconductor memory device according to a third embodiment;

FIG. 37 is a schematic X-Y cross-sectional view illustrating a part of a configuration of a semiconductor memory device according to a fourth embodiment; and

FIG. 38 is a schematic X-Y cross-sectional view illustrating a part of a configuration of a semiconductor memory device according to a fifth embodiment.

### DETAILED DESCRIPTION

A semiconductor memory device according to one embodiment includes: a substrate; a first conductive layer disposed to be separated from the substrate in a first direction intersecting with a surface of the substrate; and a memory structure having an outer peripheral surface surrounded by the first conductive layer in a first plane, the first plane being perpendicular to the first direction and including a part of the first conductive layer, wherein the memory structure includes: a first insulating layer; n (n is a natural number of three or more) first semiconductor layers disposed between the first conductive layer and the first insulating layer, the n first semiconductor layers being mutually separated in the first plane; and a gate insulating film disposed between the first conductive layer and the n first semiconductor layers in the first plane, and when an equilateral n-polygon passes through points on an outer peripheral surface of the first insulating layer and is circumscribed to the first insulating layer, the points have a shortest distance to the first conductive layer, and a range of the equilateral n-polygon is defined as a first range, in the first plane, the n first semiconductor layers are disposed inside the first range.

A semiconductor memory device according to one embodiment includes: a substrate; a first conductive layer disposed to be separated from the substrate in a first direction intersecting with a surface of the substrate; and a plurality of memory structures having outer peripheral surfaces surrounded by the first conductive layer in a first plane, the first plane being perpendicular to the first direction and including a part of the first conductive layer, wherein the memory structure includes: a first insulating layer; n (n is a natural number of three or more) first semiconductor layers each disposed between the first conductive layer and the first insulating layer, the n first semiconductor layers being mutually separated in the first plane; and a gate insulating film disposed between the first conductive layer and the n first semiconductor layers in the first plane, the outer peripheral surface of the memory structure includes n corner portions disposed corresponding to the n first semiconductor layers, and the n corner portions each include two straight portions extending along mutually intersecting directions in the first plane, and the first conductive layer includes a straight wiring portion disposed between two memory structures among the plurality of memory structures, the straight wiring portion extends along mutually parallel two straight portions included in the outer peripheral surfaces of the two memory structures, and the straight wiring portion is in contact with the two memory structures in the first plane.

Next, the semiconductor memory device according to embodiments are described in detail with reference to the drawings. The following embodiments are only examples, and not described for the purpose of limiting the present invention. The following drawings are schematic, and for convenience of description, a part of a configuration and the like is sometimes omitted. Parts common in a plurality of embodiments are attached by same reference numerals and their descriptions may be omitted.

In this specification, when referring to “semiconductor memory device,” it may mean a memory die and may mean a memory system including a controller die, such as a memory chip, a memory card, and a Solid State Drive (SSD). Further, it may mean a configuration including a host computer, such as a smartphone, a tablet terminal, and a personal computer.

In this specification, when referring to that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in OFF state, the first transistor is “electrically connected” to the third transistor.

In this specification, when referring to that the first configuration “is connected between” the second configuration and a third configuration, it may mean that the first configuration, the second configuration, and the third configuration are connected in series and the second configuration is connected to the third configuration via the first configuration.

In this specification, a direction parallel to an upper surface of the substrate is referred to as an X-direction, a direction parallel to the upper surface of the substrate and perpendicular to the X-direction is referred to as a Y-direction, and a direction perpendicular to the upper surface of the substrate is referred to as a Z-direction.

In this specification, a direction along a predetermined plane may be referred to as a first direction, a direction along this predetermined plane and intersecting with the first direction may be referred to as a second direction, and a direction intersecting with this predetermined plane may be referred to as a third direction. These first direction, second direction, and third direction may correspond to any of the X-direction, the Y-direction, and the Z-direction and need not to correspond to these directions.

Expressions, such as “above” and “below,” in this specification are based on the substrate. For example, a direction away from the substrate along the Z-direction is referred to as above and a direction approaching the substrate along the Z-direction is referred to as below. A lower surface and a lower end of a certain configuration mean a surface and an end portion on the substrate side of this configuration. An upper surface and an upper end of a certain configuration mean a surface and an end portion on a side opposite to the substrate of this configuration. A surface intersecting with the X-direction or the Y-direction is referred to as a side surface and the like.

In this specification, when referring to a “width,” a “length,” a “thickness,” or the like in a predetermined direction of a configuration, a member, or the like, this may mean a width, a length, a thickness, or the like in a cross-sectional surface or the like observed with a Scanning electron microscopy (SEM), a Transmission electron microscopy (TEM), or the like.

In this specification, when referring to that a contour of a configuration, an interface between configurations, or the like is a “straight line,” “linear,” or the like, it does not mean a mathematically strict straight line but may mean that the contour, the interface, or the like extends approximately along a straight line in a cross-sectional surface observed by SEM, TEM, or the like. In this case, for example, a virtual straight line, additional line, or the like is drawn in the cross-sectional surface observed by SEM, TEM, or the like, and the contour, the interface, or the like is assumed to extend along a straight line when a distance between the virtual straight line, additional line, or the like and each point constituting the contour, the interface, or the like is within a certain range.

### First Embodiment

[Configuration]

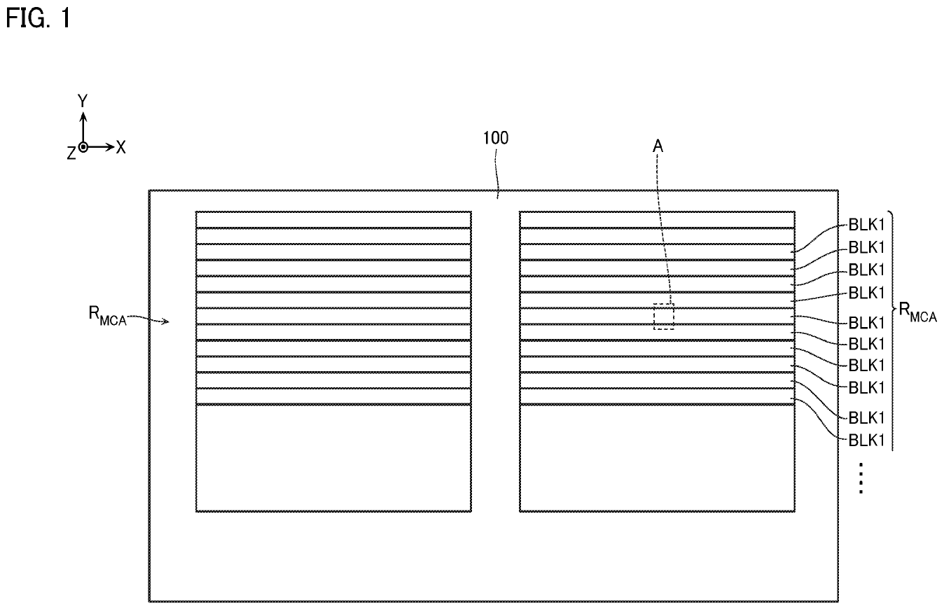

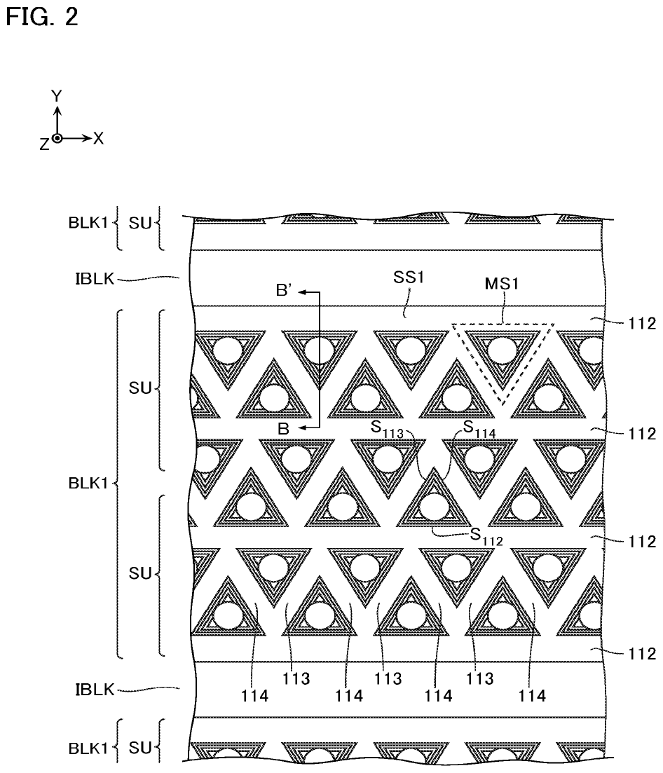

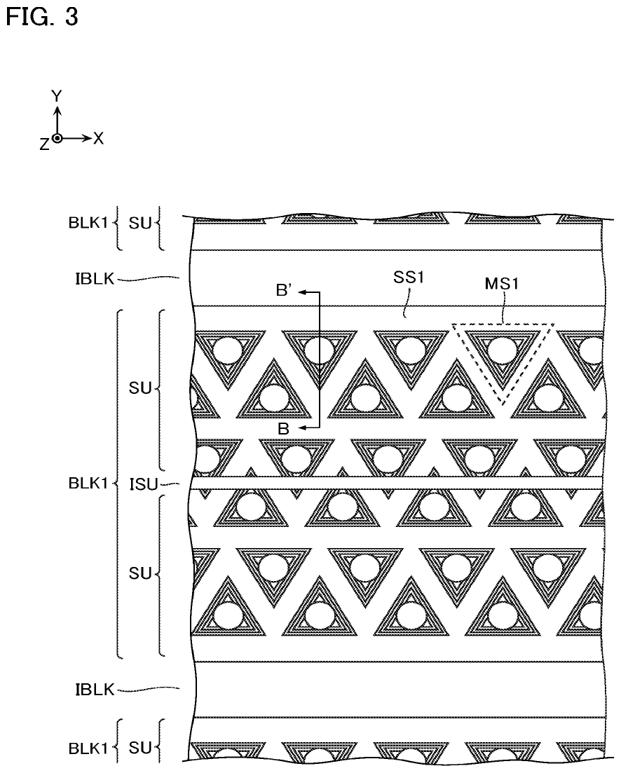

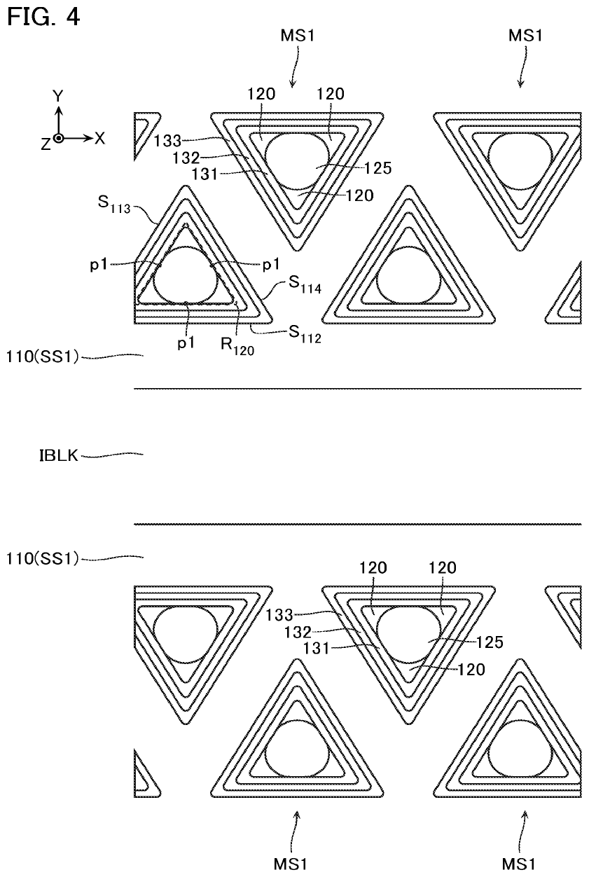

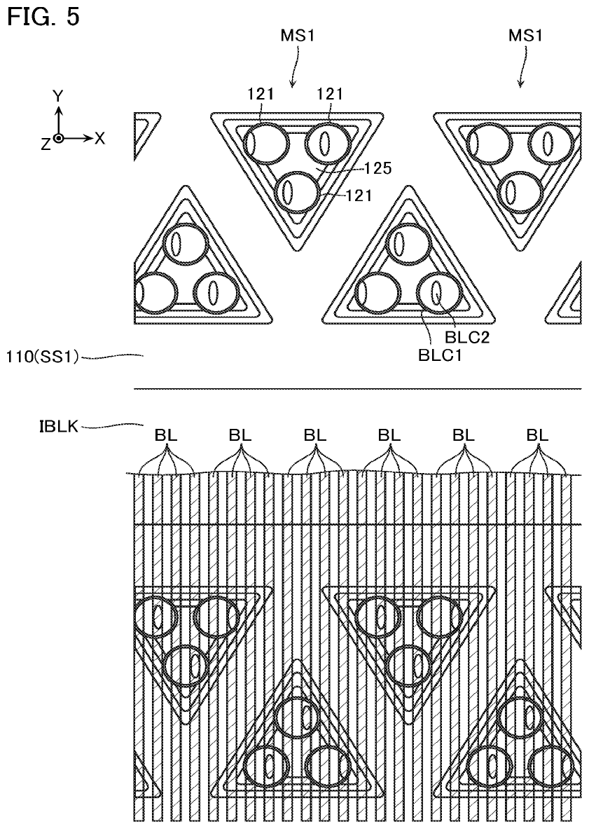

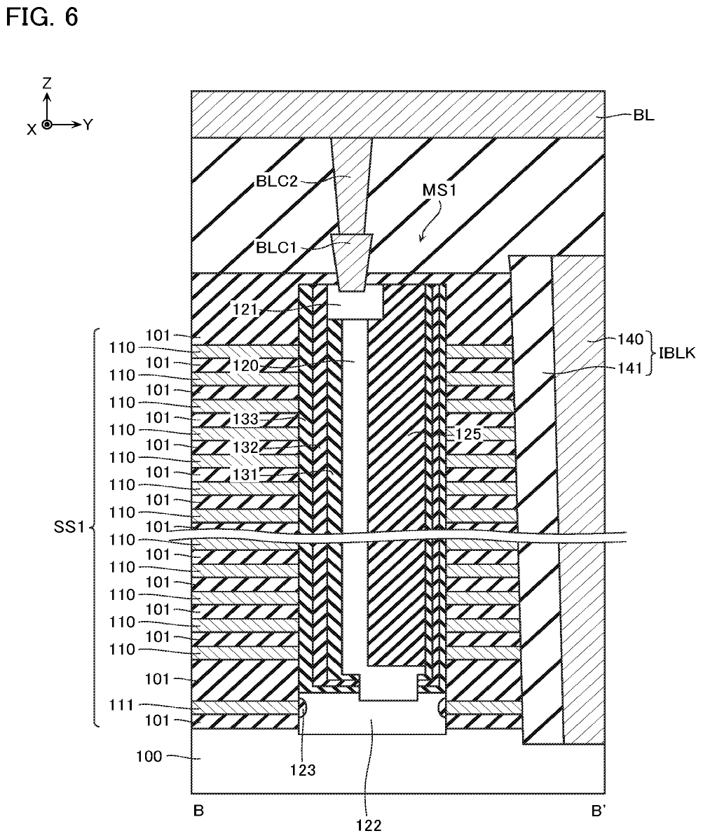

FIG. 1 is a schematic plan view illustrating a part of a configuration of a semiconductor memory device according to the embodiment. FIG. 2 and FIG. 3 are schematic X-Y cross-sectional views corresponding to a part indicated by A in FIG. 1. FIG. 2 and FIG. 3 correspond to the X-Y cross sections mutually different in height position. FIG. 4 and FIG. 5 are schematic X-Y cross-sectional views corresponding to apart of the configuration of the semiconductor memory device according to the embodiment. FIG. 4 and FIG. 5 correspond to the X-Y cross sections mutually different in height position. FIG. 6 is a schematic Y-Z cross-sectional view corresponding to a cross section of the structure illustrated in FIG. 2 and FIG. 3 taken along a line B-B′ viewed along an arrow direction.

As illustrated in FIG. 1, the semiconductor memory device according to the embodiment includes a semiconductor substrate 100. The semiconductor substrate 100 is a semiconductor substrate made of P-type silicon (Si) containing P-type impurities, such as boron (B). In the illustrated example, the semiconductor substrate 100 includes two memory cell array regions R_{MCA} arranged in the X-direction. The memory cell array region R_{MCA} includes a plurality of memory blocks BLK1 arranged in the Y-direction. For example, as illustrated in FIG. 2, inter-block structures IBLK are each disposed between the two memory blocks BLK1 mutually adjacent in the Y-direction.

For example, as illustrated in FIG. 3, the memory block BLK1 includes two string units SU arranged in the Y-direction and an inter-string unit insulating layer ISU of silicon oxide (SiO₂) or the like disposed between the two string units SU.

The memory block BLK1 includes a stacked structure SS1 and a plurality of memory structures MS1 formed in approximately equilateral triangular prism shapes. For example, in the example of FIG. 2, the stacked structure SS1 includes four straight wiring portions 112, a plurality of straight wiring portions 113, and a plurality of straight wiring portions 114. The four straight wiring portions 112 extend in the X-direction and are arranged in the Y-direction. The plurality of straight wiring portions 113 are disposed in the X-direction between the two straight wiring portions 112 mutually adjacent in the Y-direction, and extend in a direction of +60° with respect to the X-direction. The plurality of straight wiring portions 114 are disposed in the X-direction between the two straight wiring portions 112 mutually adjacent in the Y-direction, and extend in a direction of −60° with respect to the X-direction. The plurality of straight wiring portions 113 and the plurality of straight wiring portions 114 are connected in series, and connected to both of the two straight wiring portions 112 mutually adjacent in the Y-direction, thus forming a zigzag shape. The plurality of memory structures MS1 include sides S₁₁₂ in contact with the straight wiring portions 112, sides S₁₁₃ in contact with the straight wiring portions 113, and sides S₁₁₄ in contact with the straight wiring portions 114.

For example, as illustrated in FIG. 6, the stacked structure SS1 includes a plurality of conductive layers 110 arranged in the Z-direction, a conductive layer 111 disposed below the plurality of conductive layers 110, and insulating layers 101 disposed between the two conductive layers 110, 111 mutually adjacent in the Z-direction.

The conductive layer 110 is an approximately plate-shaped conductive layer extending in the X-direction. The conductive layer 110 includes, for example, a stacked film of a barrier conductive film of titanium nitride (TiN) or the like and a metal film of tungsten (W) or the like. For example, as illustrated in FIG. 2, the conductive layer 110 basically has a width in the Y-direction similar to that of the memory block BLK1. However, for example, as illustrated in FIG. 3, a part of the conductive layers 110 disposed in the upper portion are separated in the Y-direction by the inter-string unit insulating layer ISU, thus having the widths in the Y-direction equal to or less than a half of the widths in the Y-direction of the memory block BLK1. The conductive layer 110 functions as, for example, a gate electrode and a word line of a memory transistor (memory cell), or a gate electrode and a select gate line of a select transistor.

The conductive layer 111 (FIG. 6) includes, for example, a stacked film of a barrier conductive film of titanium nitride (TiN) or the like and a metal film of tungsten (W) or the like. The insulating layer 101 includes an insulating layer of silicon oxide (SiO₂) or the like. The conductive layer 111 functions as, for example, a gate electrode and a select gate line of a select transistor.

For example, as illustrated in FIG. 4, the memory structure MS1 has an outer peripheral surface surrounded over the whole circumference by the conductive layer 110, 111 in the stacked structure SS1.

The memory structure MS1 includes an insulating layer 125 of silicon oxide (SiO₂) or the like and three semiconductor layers 120. The insulating layer 125 is disposed on the center axis of the memory structure MS1. The three semiconductor layers 120 are disposed along an outer peripheral surface of the insulating layer 125 at intervals of 120°, and mutually separated. The insulating layer 125 and the three semiconductor layers 120 constitute a structure of approximately equilateral triangle shape in the X-Y cross section. For example, FIG. 4 illustrates three points p1 of the outer peripheral surface of the insulating layer 125, and a distance to the conductive layer 110 is the shortest at these points p1. FIG. 4 also illustrates an equilateral triangular range R₁₂₀ passing through the three points p1 and circumscribed to the insulating layer 125. In the illustrated example, the three semiconductor layers 120 are all disposed within a range of the range R₁₂₀. The respective sides of the equilateral triangle forming the range R₁₂₀ are parallel to the above-described three sides S₁₁₂, S₁₁₃, and S₁₁₄. The memory structure MS1 includes a tunnel insulating film 131, an electric charge accumulating film 132, and a block insulating film 133 covering the outer peripheral surface of the approximately equilateral triangular structure.

The semiconductor layer 120 functions as, for example, channel regions of a plurality of memory transistors and a select transistor arranged in the Z-direction. The semiconductor layer 120 is a semiconductor layer of polycrystalline silicon (Si) or the like. For example, as illustrated in FIG. 6, the semiconductor layer 120 has an approximately triangular prism shape. A part of the outer peripheral surface of the semiconductor layer 120 opposes the conductive layer 110. A part of the outer peripheral surface of the semiconductor layer 120 is in contact with the insulating layer 125.

The semiconductor layer 120 has an upper end portion in which an impurity region 121 containing N-type impurities, such as phosphorus (P), is disposed. The impurity region 121 is electrically connected to a bit line BL via a contact BLC1 and a contact BLC2. For example, as illustrated in FIG. 5, positions in the X-direction of a plurality of impurity regions 121 included in a plurality of memory structures MS1 arranged in the X-direction are all different. The contacts BLC1, BLC2 may be disposed at positions overlapping the impurity regions 121 viewed in the Z-direction. Positions in the X-direction of a plurality of contacts BLC2 included in one string unit SU (FIG. 3) are all different. Therefore, a plurality of impurity regions 121 included in one string unit SU are connected to the respective different bit lines BL.

For example, as illustrated in FIG. 6, the semiconductor layer 120 has a lower end portion connected to a P-type well region of the semiconductor substrate 100 via a semiconductor layer 122 made of single-crystal silicon (Si) or the like. The semiconductor layer 122 functions as, for example, a channel region of the select transistor. The semiconductor layer 122 has an outer peripheral surface surrounded by the conductive layer 111 and opposed to the conductive layer 111. An insulating layer 123 of silicon oxide (SiO₂) or the like is disposed between the semiconductor layer 122 and the conductive layer 111.

The tunnel insulating film 131, the electric charge accumulating film 132, and the block insulating film 133 function as, for example, gate insulating films of the memory transistor and the select transistor. The tunnel insulating film 131 and the block insulating film 133 are insulating films of silicon oxide (SiO₂) or the like. The electric charge accumulating film 132 is a film of silicon nitride (Si₃N₄) or the like that can accumulate an electric charge. The tunnel insulating film 131, the electric charge accumulating film 132, and the block insulating film 133 have a shape of an approximately equilateral triangular cylinder, and extend in the Z-direction along the outer peripheral surface of the approximately equilateral triangular structure including the insulating layer 125 and the three semiconductor layers 120.

The inter-block structure IBLK includes a conductive layer 140 extending in the Z-direction and the X-direction, and an insulating layer 141 disposed on a side surface of the conductive layer 140. The conductive layer 140 is connected to an N-type impurity region (not illustrated) disposed to the semiconductor substrate 100. The conductive layer 140 may include, for example, a stacked film of a barrier conductive film of titanium nitride (TiN) or the like and a metal film of tungsten (W) or the like. The conductive layer 140 functions as, for example, a part of a source line.

[Manufacturing Method]

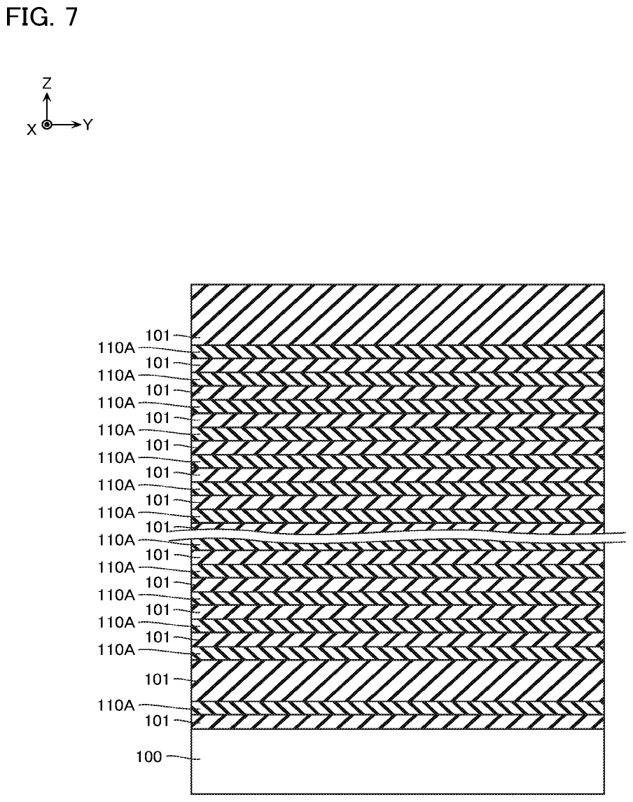

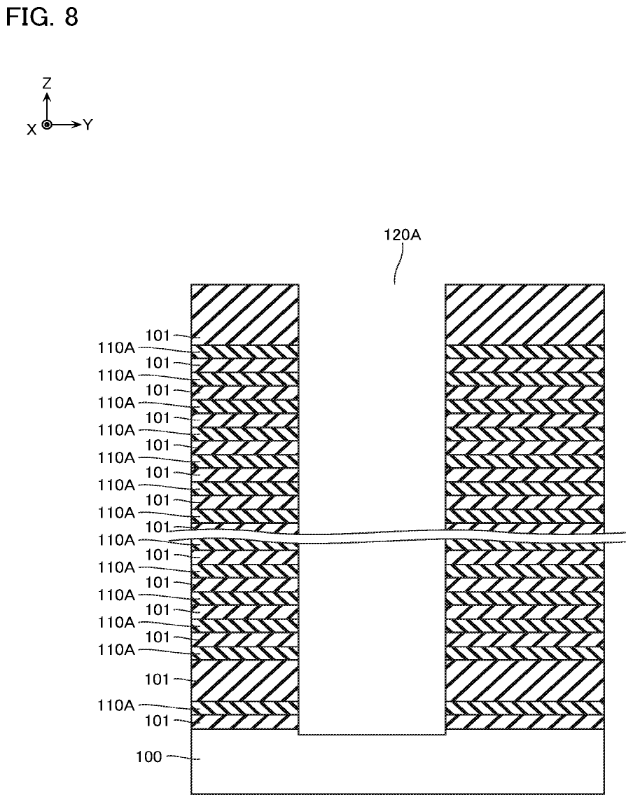

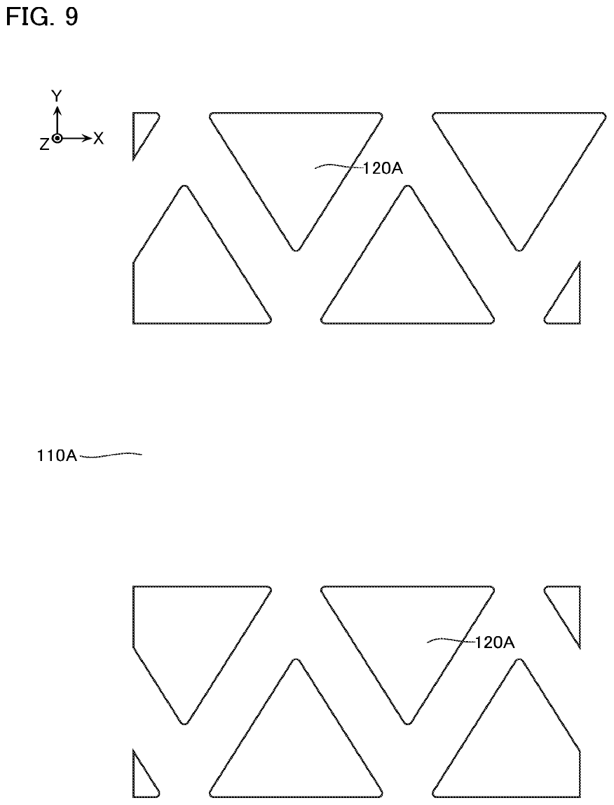

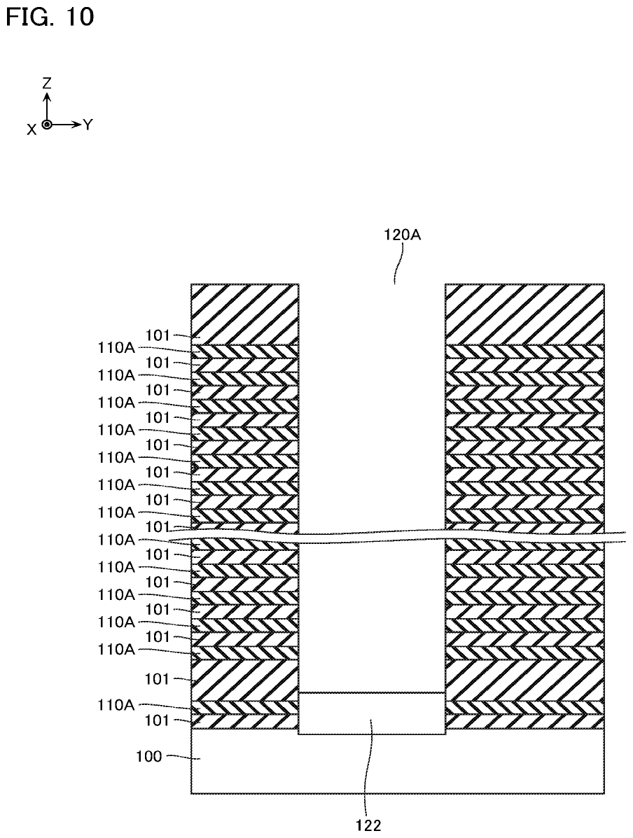

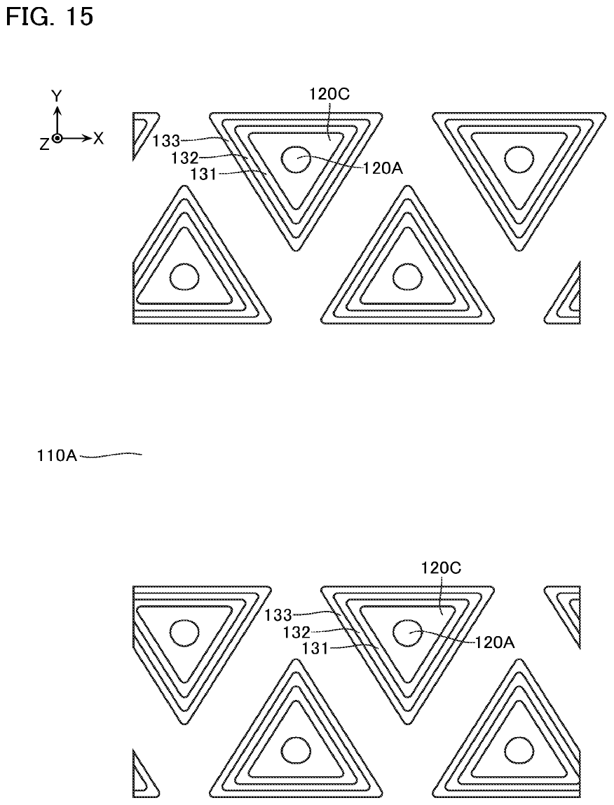

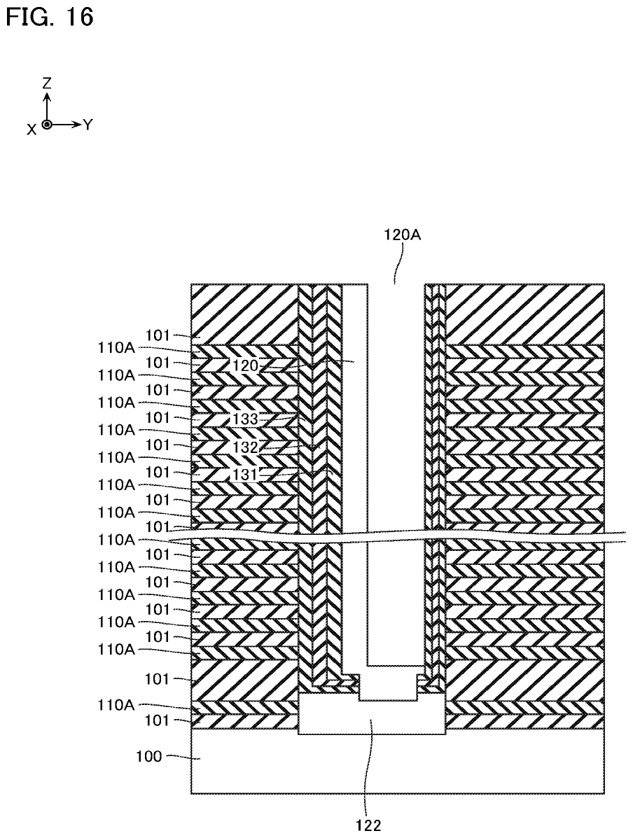

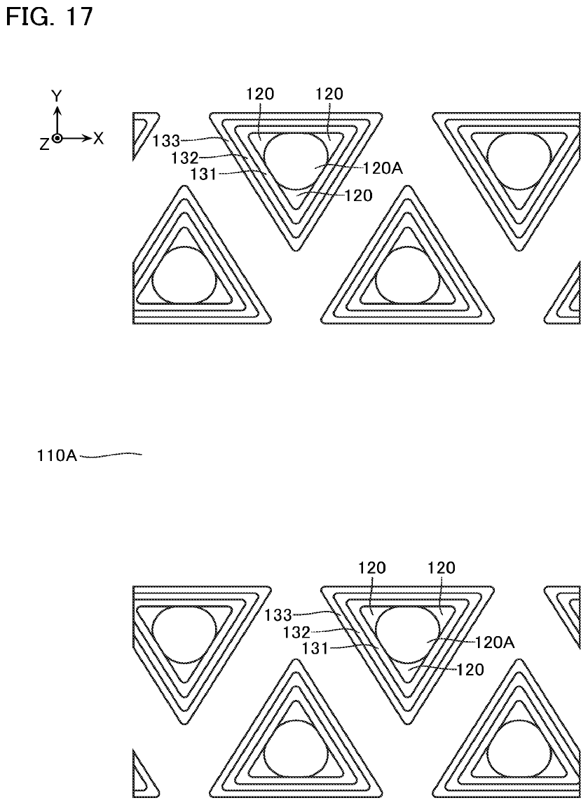

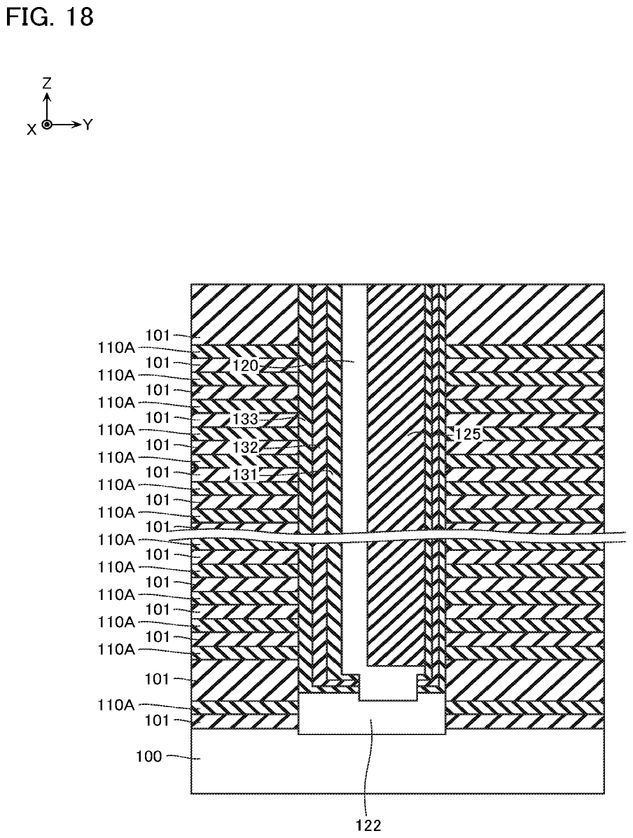

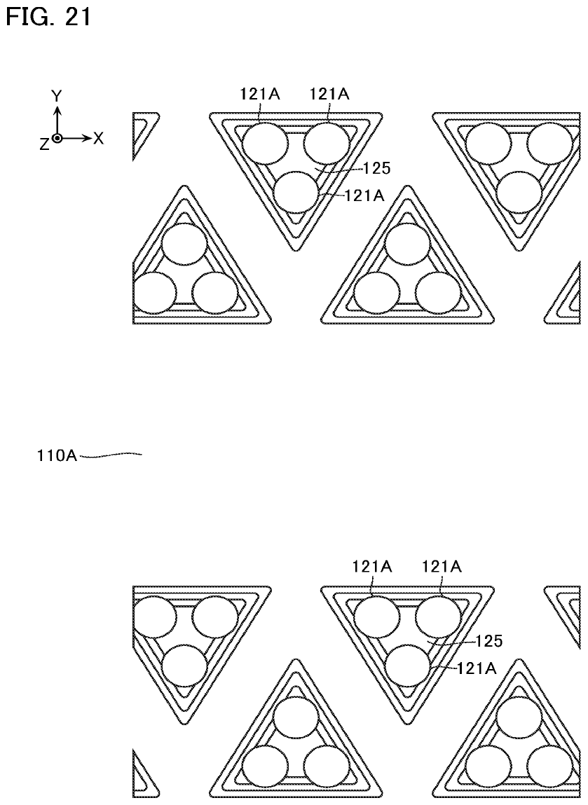

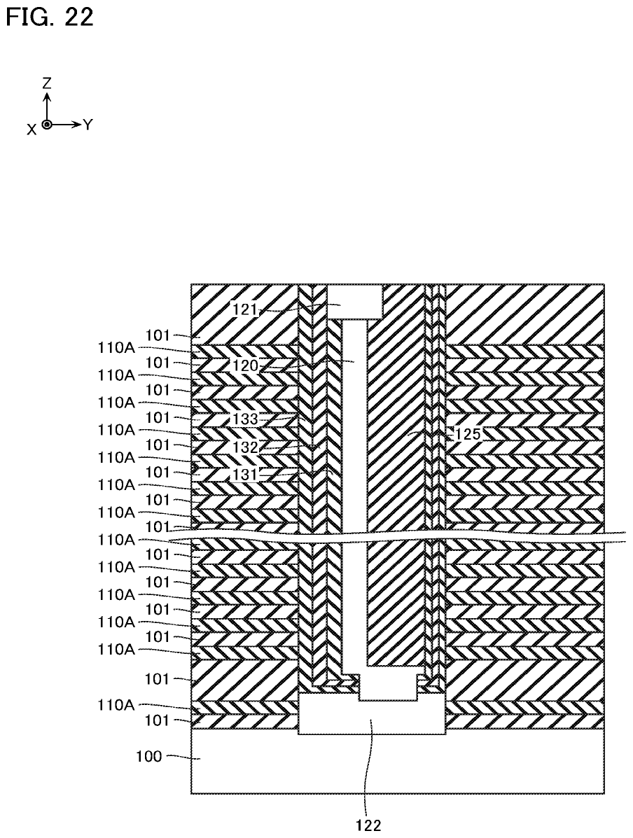

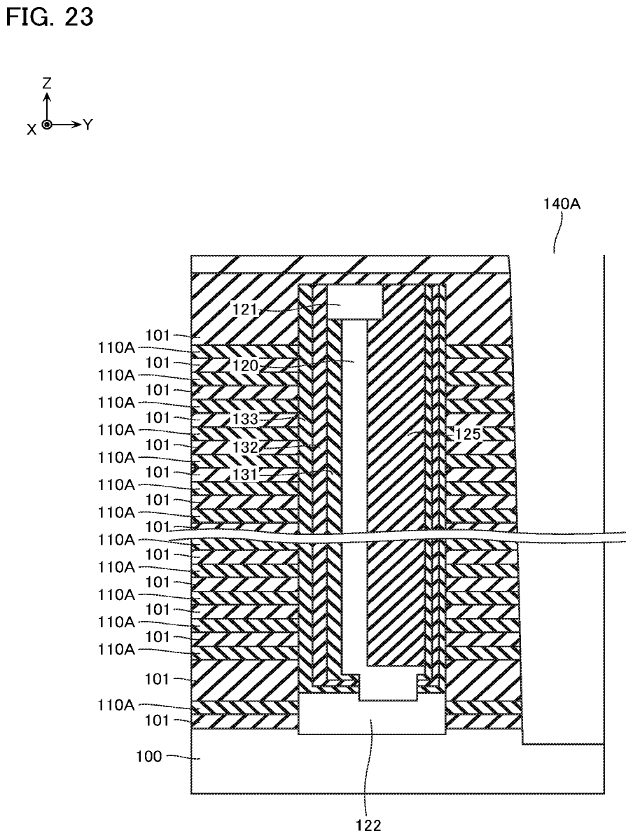

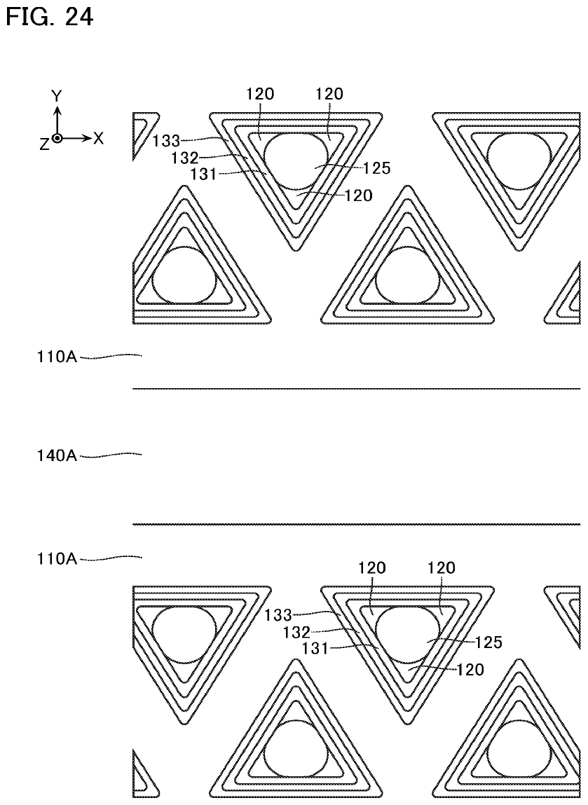

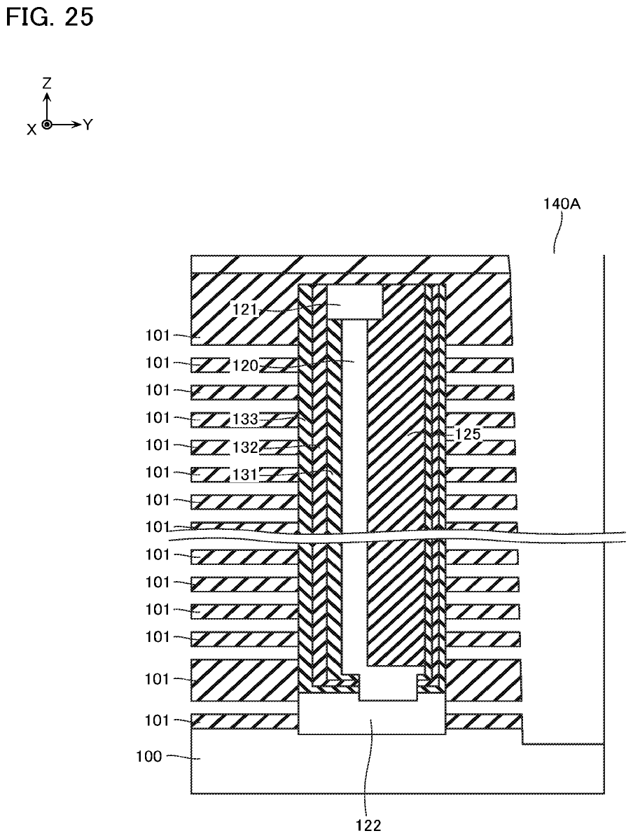

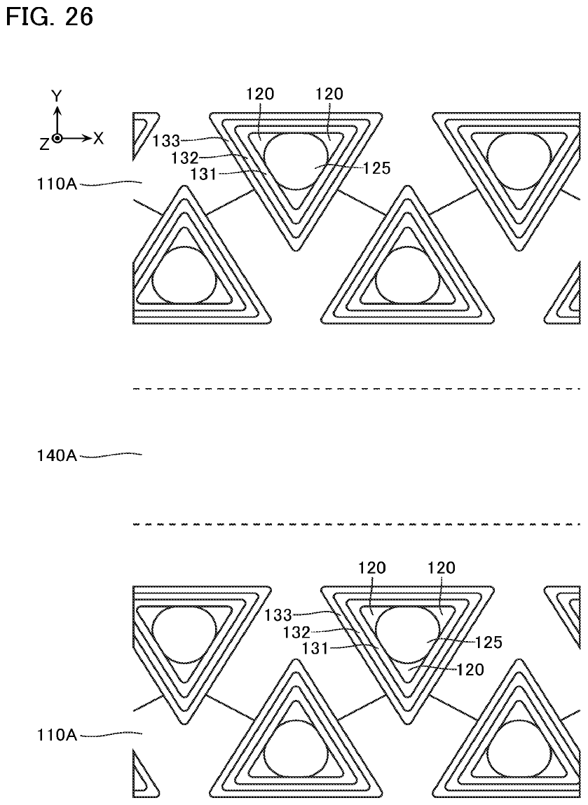

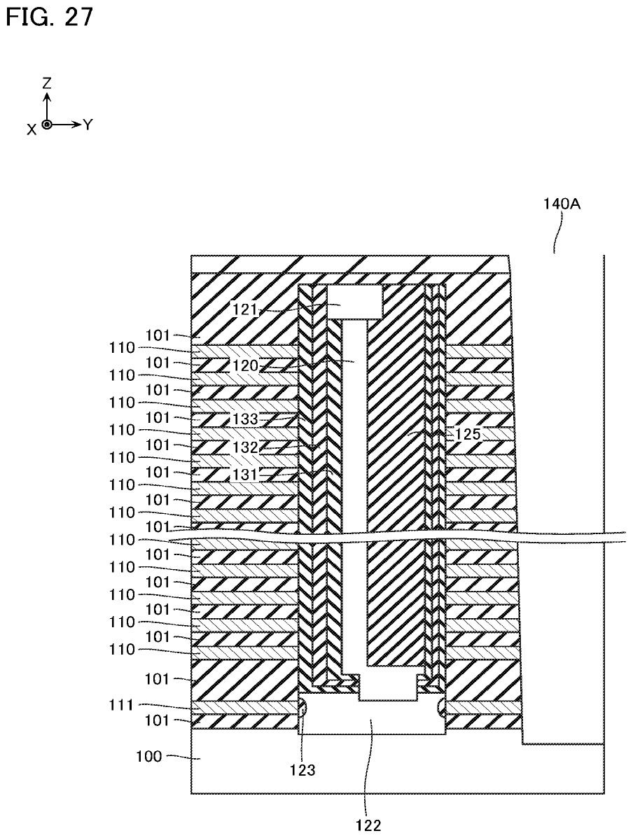

Next, with reference to FIG. 7 to FIG. 27, a method for manufacturing the semiconductor memory device according to the embodiment will be described. FIG. 7, FIG. 8, FIG. 10 to FIG. 14, FIG. 16, FIG. 18 to FIG. 20, FIG. 22, FIG. 23, FIG. 25, and FIG. 27 are schematic Y-Z cross-sectional views for describing the manufacturing method, and illustrate the cross sections corresponding to FIG. 6. FIG. 9, FIG. 15, FIG. 17, FIG. 24, and FIG. 26 are schematic X-Y cross-sectional views for describing the manufacturing method, and illustrate the cross sections corresponding to FIG. 5. FIG. 21 is a schematic X-Y cross-sectional view for describing the manufacturing method.

In the manufacture of the semiconductor memory device according to the embodiment, for example, as illustrated in FIG. 7, a plurality of sacrifice layers 110A and insulating layers 101 are formed on the semiconductor substrate 100. The sacrifice layer 110A is made of silicon nitride (SiN) or the like. This process is performed by a method, such as CVD (Chemical Vapor Deposition).

Next, for example, as illustrated in FIG. 8 and FIG. 9, a plurality of through-holes 120A are formed at positions corresponding to the plurality of memory structures MS1. The through-hole 120A is a through-holes that extends in the Z-direction and penetrates the insulating layers 101 and the sacrifice layers 110A, thus exposing an upper surface of the semiconductor substrate 100. This process is performed by a method, such as RIE.

Next, for example, as illustrated in FIG. 10, a semiconductor layer 122 is formed on a bottom surface of the through-hole 120A. This process is performed by a method, such as an epitaxial growth.

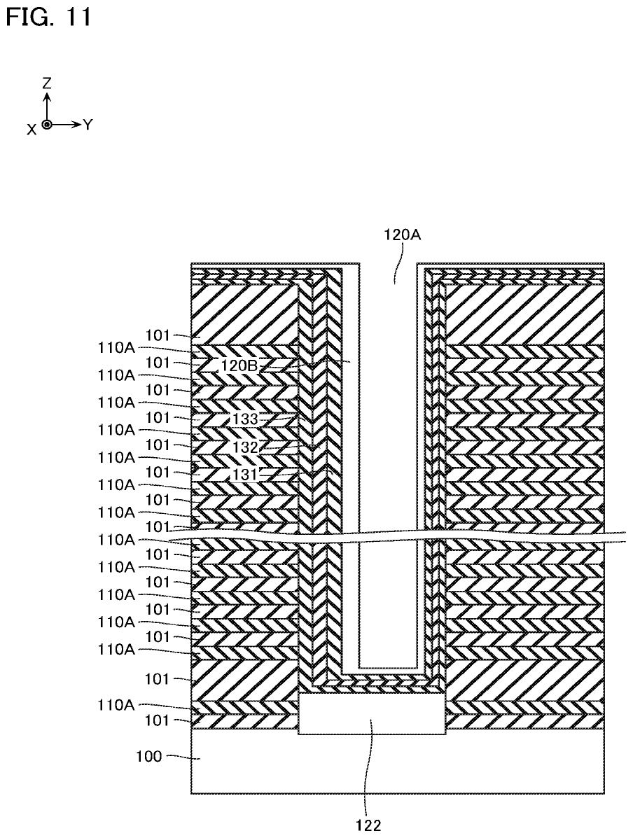

Next, for example, as illustrated in FIG. 11, the block insulating film 133, the electric charge accumulating film 132, the tunnel insulating film 131, and an amorphous silicon film 120B are formed on an upper surface of the semiconductor layer 122 and an inner peripheral surface of the through-hole 120A. This process is performed by a method, such as CVD.

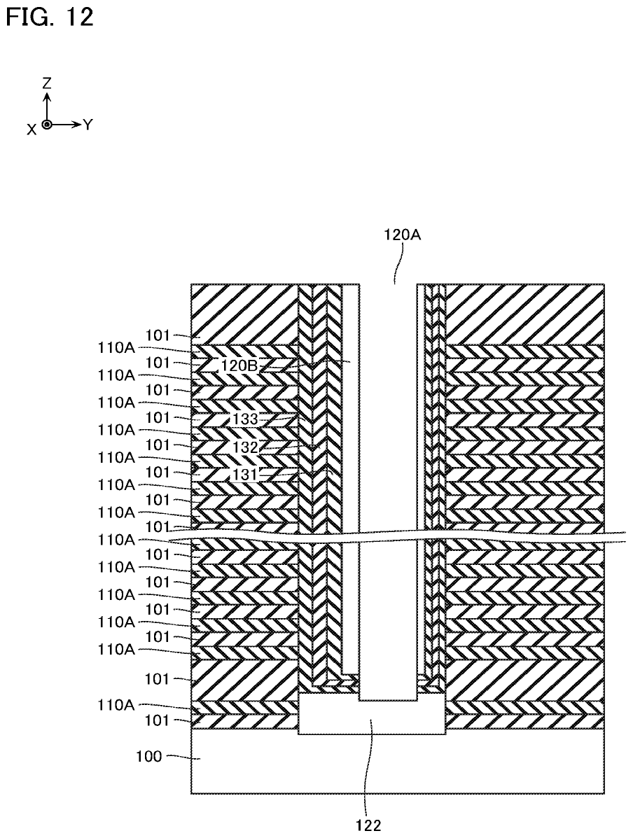

Next, for example, as illustrated in FIG. 12, a part of the block insulating film 133, the electric charge accumulating film 132, the tunnel insulating film 131, and the amorphous silicon film 120B covering the upper surface of the semiconductor layer 122 is removed. This process is performed by a method, such as RIE.

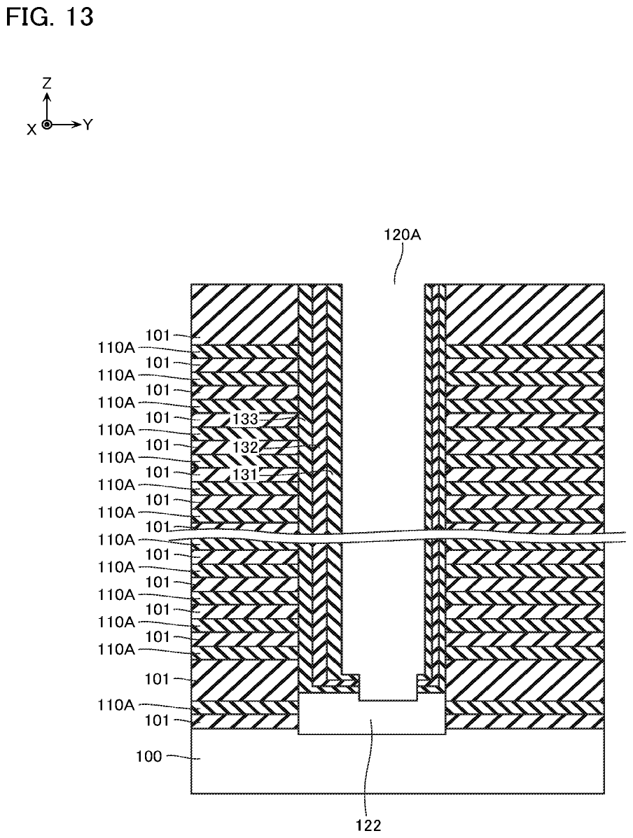

Next, for example, as illustrated in FIG. 13, the amorphous silicon film 120B is removed. This process is performed by a method, such as wet etching.

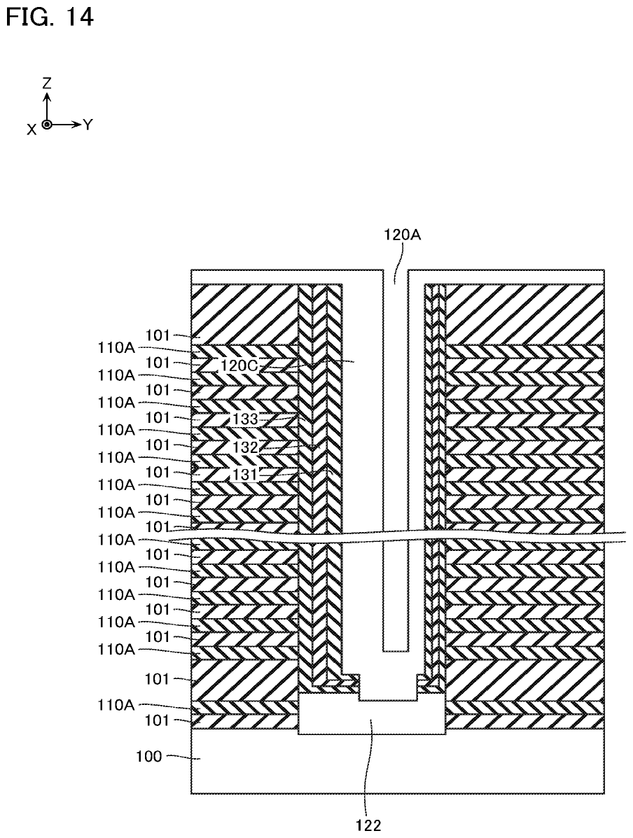

Next, for example, as illustrated in FIG. 14 and FIG. 15, a semiconductor layer 120C is formed on the upper surface of the semiconductor layer 122 and the inner peripheral surface of the through-hole 120A. This process is performed by a method, such as CVD.

Next, for example, as illustrated in FIG. 16 and FIG. 17, the semiconductor layer 120C is separated into three parts, thus forming the mutually separated three semiconductor layers 120. This process is performed by a method, such as wet etching.

Next, for example, as illustrated in FIG. 18, an insulating layer 125 is formed inside the through-hole 120A. This process is performed by a method, such as CVD. In this process, the through-hole 120A is filled.

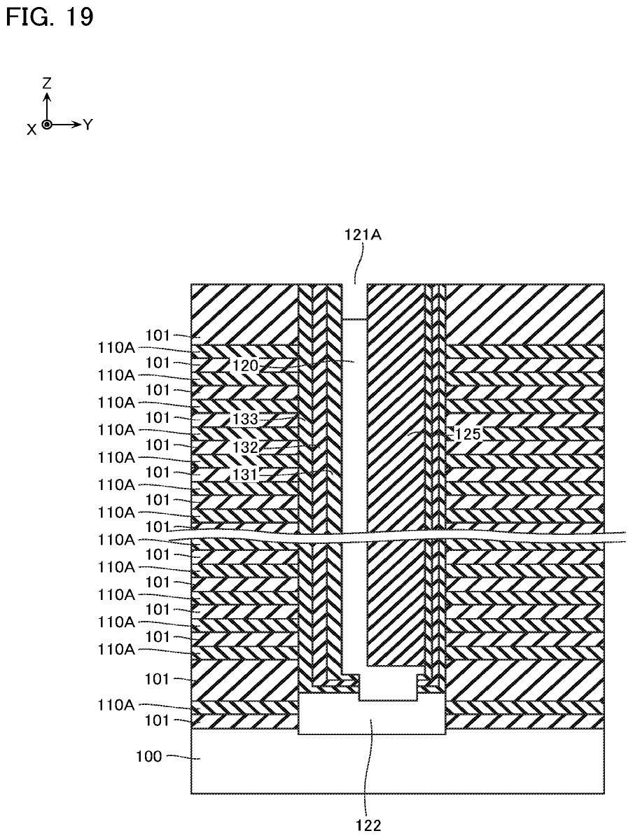

Next, for example, as illustrated in FIG. 19, a part of the semiconductor layer 120 is removed to form a recessed portion 121A. This process is performed by a method, such as wet etching.

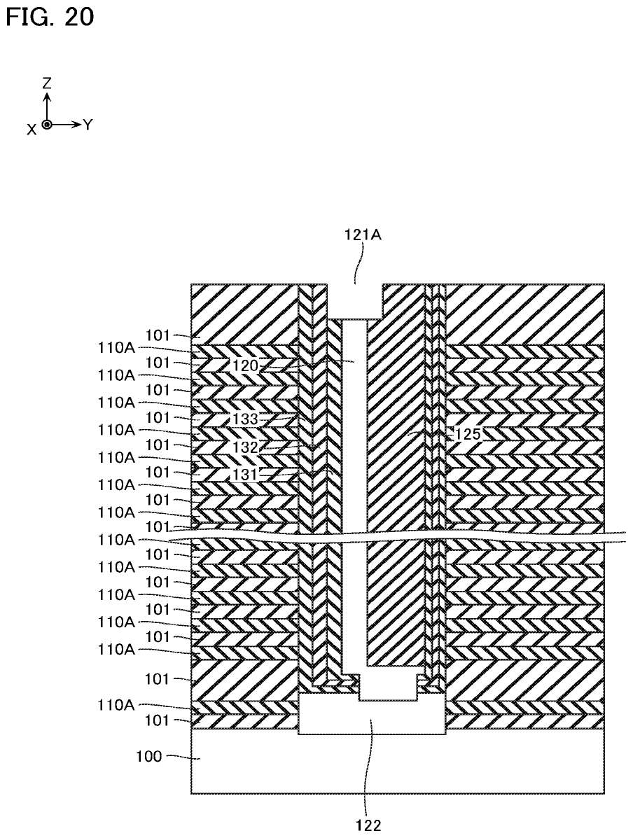

Next, for example, as illustrated in FIG. 20 and FIG. 21, the tunnel insulating film 131 and the insulating layer 125 are partially removed via the recessed portion 121A. This process is performed by a method, such as wet etching.

Next, for example, as illustrated in FIG. 22, the impurity region 121 is formed inside the recessed portion 121A. This process is performed by a method, such as CVD and RIE.

Next, for example, as illustrated in FIG. 23 and FIG. 24, a trench 140A is formed. The trench 140A is a trench that extends in the Z-direction and the X-direction and separates the insulating layers 101 and the sacrifice layers 110A in the Y-direction, thus exposing the upper surface of the semiconductor substrate 100. This process is performed by a method, such as RIE.

Next, for example, as illustrated in FIG. 25, the sacrifice layers 110A are removed via the trench 140A. This forms a hollow structure including the plurality of insulating layers 101 disposed in the Z-direction and the structure (semiconductor layer 120, tunnel insulating film 131, electric charge accumulating film 132, block insulating film 133, and insulating layer 125) inside the through-hole 120A supporting the insulating layers 101. This process is performed by a method, such as wet etching.

In this process, a liquid etchant or the like is supplied from the trench 140A. Accordingly, for example, as illustrated in FIG. 26, the sacrifice layers 110A are gradually removed from the parts close to the trench 140A. In the example of FIG. 26, the sacrifice layer 110A is removed up to a part of the part corresponding to the above-described straight wiring portions 113, 114.

Next, for example, as illustrated in FIG. 27, the insulating layer 123 is formed. This process is performed by a method, such as an oxidized treatment.

Next, for example, as illustrated in FIG. 27, the conductive layers 110 and the conductive layer 111 are formed. This process is performed by a method, such as CVD.

Subsequently, the inter-block structure IBLK, the contacts BLC1 and BLC2, the bit line BL, and the like are formed, thus manufacturing the semiconductor memory device according to the first embodiment.

### Comparative Example

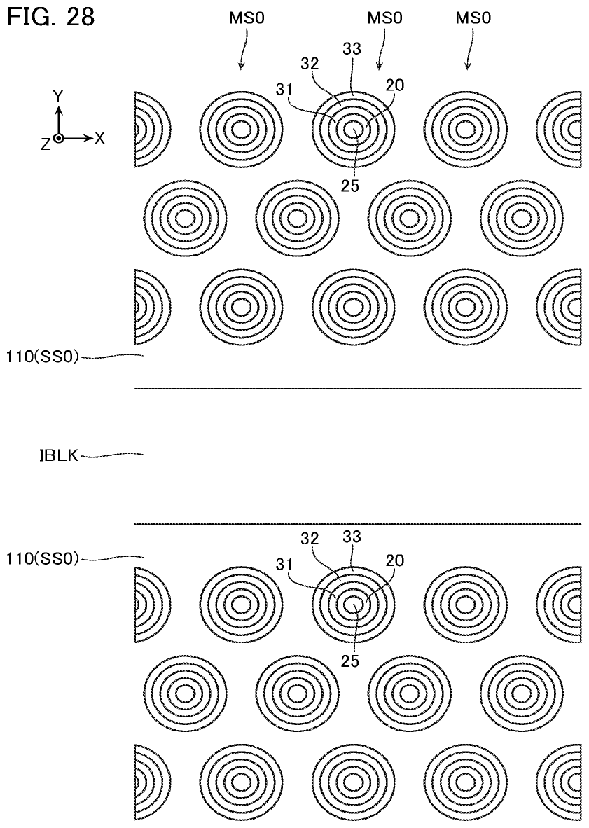

Next, with reference to FIG. 28 to FIG. 32, a semiconductor memory device according to the comparative example will be described.

FIG. 28 is a schematic X-Y cross-sectional view for describing a configuration of the semiconductor memory device according to the comparative example.

The semiconductor memory device according to the comparative example includes a stacked structure SS0 and a plurality of memory structures MS0 formed in an approximately columnar shape. The stacked structure SS0 does not include the straight wiring portions 112, 113 or the like as described with reference to FIG. 2 and the like.

The stacked structure SS0 includes a plurality of conductive layers 110 arranged in the Z-direction, a conductive layer 111 disposed below the plurality of conductive layers 110, and insulating layers 101 disposed between the two conductive layers 110, 111 mutually adjacent in the Z-direction.

The memory structure MS0 includes an insulating layer 25 of silicon oxide (SiO₂) or the like, an approximately cylindrically-shaped semiconductor layer 20, a tunnel insulating film 31, an electric charge accumulating film 32, and a block insulating film 33. The insulating layer 25 is disposed on the center axis of the memory structure MS0. The semiconductor layer 20 covers an outer peripheral surface of the insulating layer 25. The tunnel insulating film 31 covers an outer peripheral surface of the semiconductor layer 20.

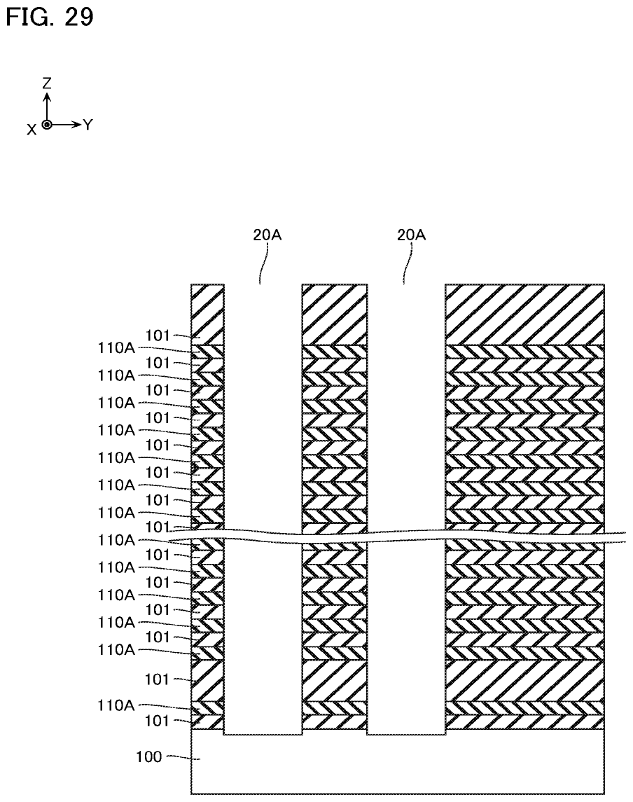

FIG. 29 to FIG. 32 are schematic X-Y cross-sectional views for describing a method for manufacturing the semiconductor memory device according to the comparative example.

In the manufacturing process of the semiconductor memory device according to the comparative example, for example, the process described with reference to FIG. 7 is performed.

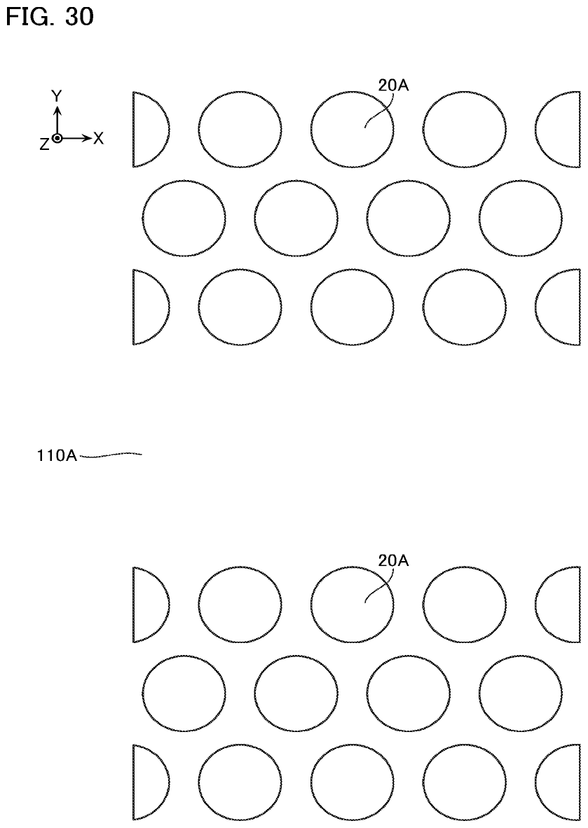

Next, for example, as illustrated in FIG. 29 and FIG. 30, a plurality of through-holes 20A are formed at positions corresponding to the plurality of memory structures MS0. The through-hole 20A is a through-hole that extends in the Z-direction and penetrates the insulating layers 101 and the sacrifice layers 110A, thus exposing the upper surface of the semiconductor substrate 100. This process is performed by a method, such as RIE.

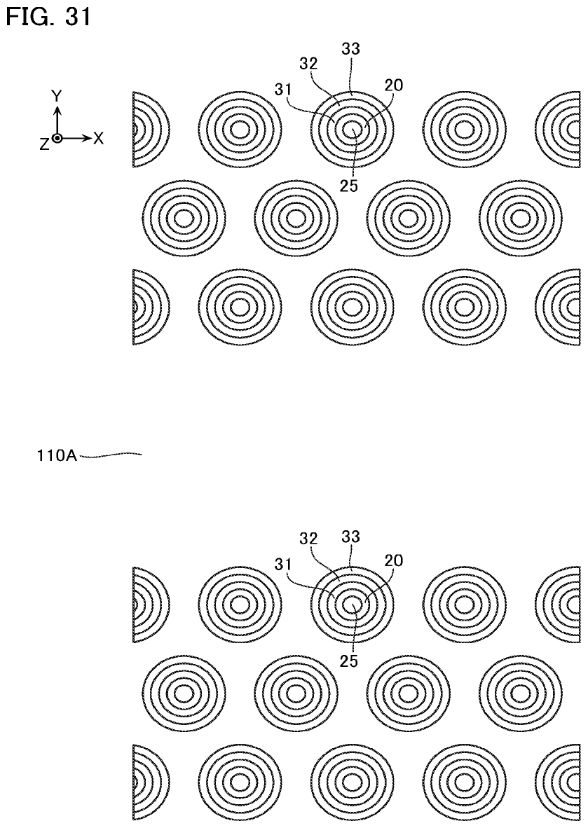

Next, for example, the processes described with reference to FIG. 10 to FIG. 15 and FIG. 18 are performed. Accordingly, for example, as illustrated in FIG. 31, the block insulating film 33, the electric charge accumulating film 32, the tunnel insulating film 31, the semiconductor layer 20, and the insulating layer 25 are formed inside the through-hole 20A.

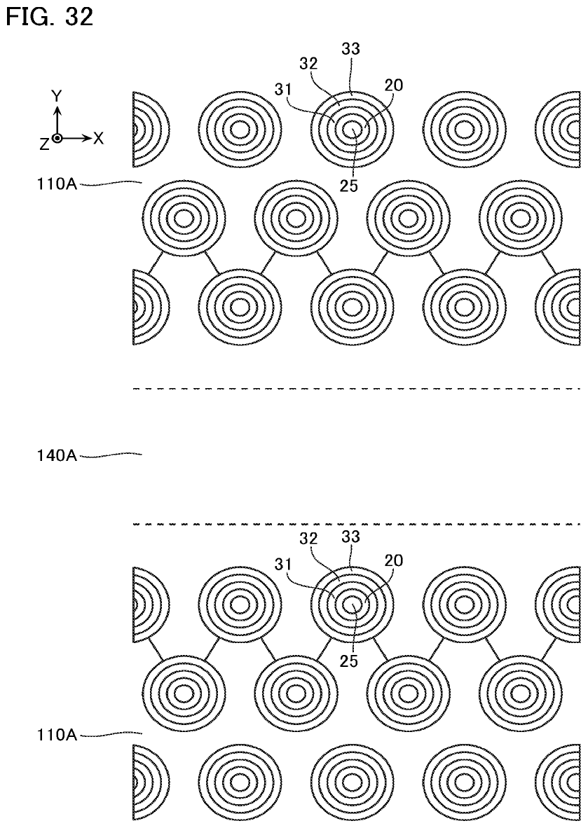

Subsequently, for example, the processes following the process described with reference to FIG. 23 are performed. FIG. 32 illustrates a state during the processes corresponding to the processes described with reference to FIG. 25 and FIG. 26.

[Effect]

When the semiconductor memory device according to the comparative example is highly integrated in the Z-direction, for example, it is considered to increase the number of the conductive layers 110 included in the stacked structure SS0. In this case, in the processes described with reference to FIG. 29 and FIG. 30, an aspect ratio of the through-hole 20A increases in some cases. In this case, for example, a lower end of the through-hole 20A possibly does not reach the semiconductor substrate 100. Therefore, the semiconductor memory device possibly fails to be appropriately manufactured.

When the semiconductor memory device according to the comparative example is highly integrated in the X-Y plane, for example, it is considered to decrease the distance between the memory structures MS0. In this case, in the processes described with reference to FIG. 29 and FIG. 30, a distance between the through-holes 20A decreases. In this case, for example, the through-holes 20A are possibly mutually communicated. In the processes described with reference to FIG. 25 to FIG. 27, the sacrifice layers 110A possibly fail to be appropriately removed, or the conductive layers 110 possibly fail to be appropriately formed.

Here, in the first embodiment, in the processes described with reference to FIG. 8 and FIG. 9, the plurality of approximately equilateral triangular through-holes 120A are formed. The plurality of through-holes 120A are disposed to be mutually adjacent via mutually parallel sides. In the processes described with reference to FIG. 14 to FIG. 17, the three semiconductor layers 120 are formed inside the plurality of through-holes 120A.

Here, while the through-hole 20A according to the comparative example corresponds to one semiconductor layer 20, the through-hole 120A according to the first embodiment corresponds to the three semiconductor layers 120.

Accordingly, when the semiconductor layers 20, 120 are disposed with the same density, the inner diameter of the through-hole 120A according to the first embodiment can be larger than that of the through-hole 20A according to the comparative example. In this case, it is easier to cause the lower end of the through-hole 120A according to the first embodiment to reach the semiconductor substrate 100 than to cause the lower end of the through-hole 20A according to the comparative example to reach the semiconductor substrate 100.

When the semiconductor layers 20, 120 are disposed with the same density, the distance between the through-holes 120A according to the first embodiment can be larger than the distance between the through-holes 20A according to the comparative example. In this case, the possibility that the through-holes 120A according to the first embodiment are mutually communicated is lower than the possibility that the through-holes 20A according to the comparative example are mutually communicated. The removal of the sacrifice layers 110A and the formation of the conductive layers 110 can be appropriately performed.

Especially, in this embodiment, in the processes described with reference to FIG. 8 and FIG. 9, the plurality of through-holes 120A are disposed to be mutually adjacent via the mutually parallel sides. This allows more appropriately reducing the communication between the through-holes 120A, thereby allowing more appropriately performing the removal of the sacrifice layers 110A and the formation of the conductive layers 110.

### Second Embodiment

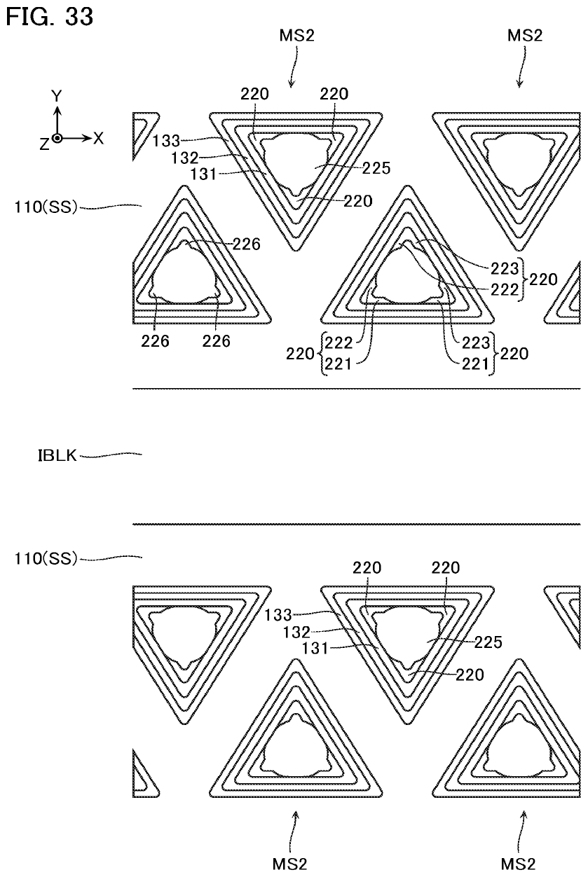

Next, with reference to FIG. 33, a configuration of a semiconductor memory device according to the second embodiment will be described. FIG. 33 is a schematic X-Y cross-sectional view for describing a part of the configuration of the semiconductor memory device according to the second embodiment.

The semiconductor memory device according to the second embodiment is basically configured similarly to the semiconductor memory device according to the first embodiment. However, the semiconductor memory device according to the second embodiment includes a memory structure MS2 instead of the memory structure MS1.

The memory structure MS2 according to the second embodiment is basically configured similarly to the memory structure MS1 according to the first embodiment. However, for example, as illustrated in FIG. 33, the memory structure MS2 according to the second embodiment includes an insulating layer 225 and semiconductor layers 220 instead of the insulating layer 125 and the semiconductor layers 120.

The insulating layer 225 and the semiconductor layer 220 according to the second embodiment are basically configured similarly to the insulating layer 125 and the semiconductor layer 120 according to the first embodiment. However, while the semiconductor layer 120 has the approximately triangular prism shape, the semiconductor layer 220 according to the second embodiment includes two of a part 221, a part 222, and a part 223. The part 221 extends along the side surface of the tunnel insulating film 131 in the X-direction. The part 222 extends along the side surface of the tunnel insulating film 131 in a direction of +60° with respect to the X-direction. The part 223 extends along the side surface of the tunnel insulating film 131 in a direction of −60° with respect to the X-direction. The insulating layer 225 includes projecting portions 226 disposed at intervals of 120° corresponding to the three semiconductor layers 220 in the X-Y cross section. The projecting portions 226 project toward apexes of an equilateral triangle circumscribed to the memory structure MS2 so as to contact the two parts.

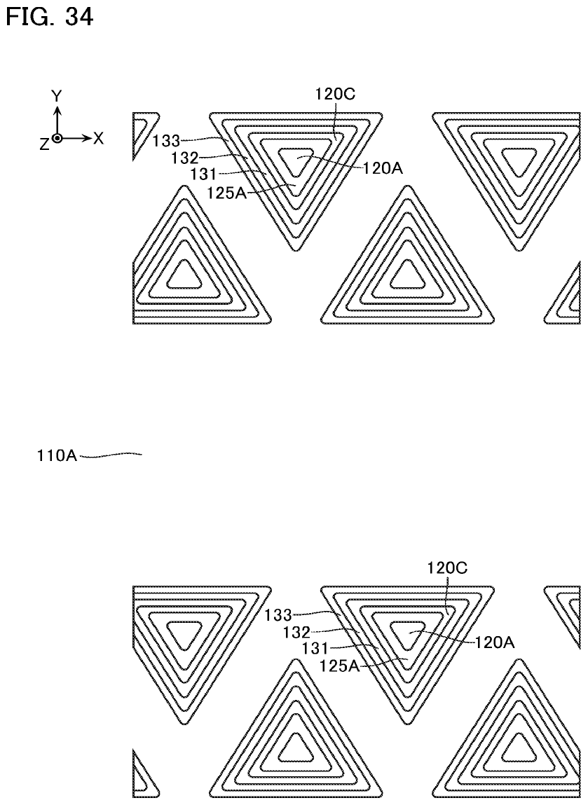

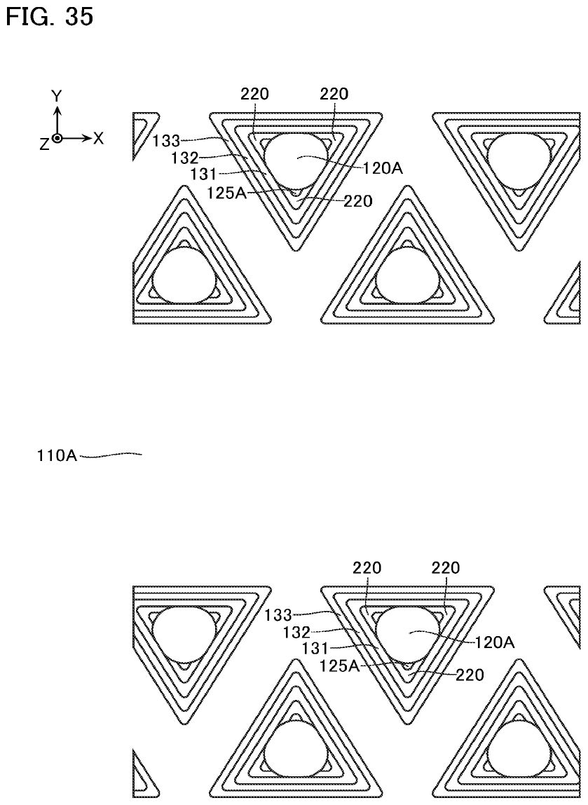

Next, with reference to FIG. 34 and FIG. 35, a method for manufacturing the semiconductor memory device according to the second embodiment will be described. FIG. 34 and FIG. 35 are schematic X-Y cross-sectional views for describing the method for manufacturing the semiconductor memory device according to the second embodiment.

The method for manufacturing the semiconductor memory device according to the second embodiment is basically similar to the method for manufacturing the semiconductor memory device according to the first embodiment. However, in the processes with reference to FIG. 14 and FIG. 15, after forming the semiconductor layer 120C, an insulating layer 125A is further formed inside the through-hole 120A as illustrated in FIG. 34. In the processes described with reference to FIG. 16 and FIG. 17, not only the semiconductor layer 120C, but also the insulating layer 125A is separated into three parts as illustrated in FIG. 35. The respective three insulating layers 125A separated in this process become the above-described three projecting portions 226.

### Third Embodiment

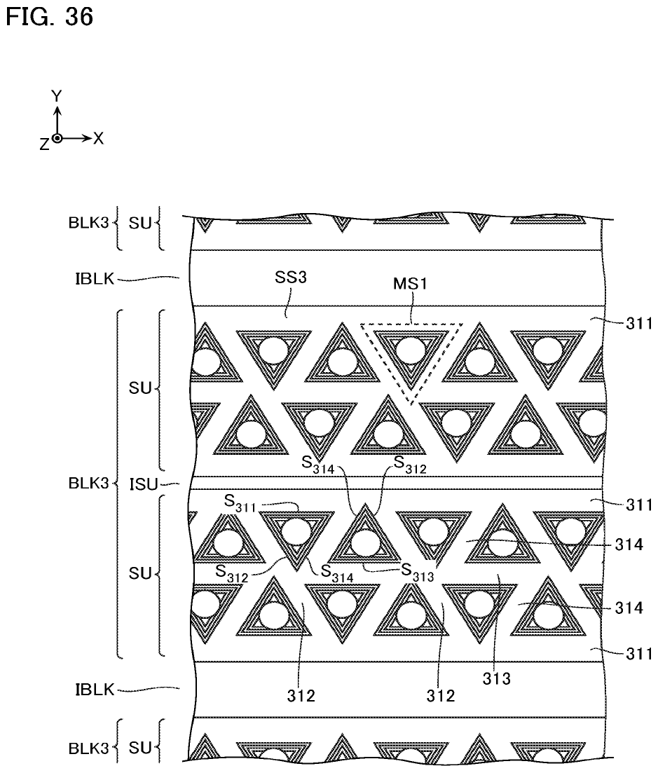

Next, with reference to FIG. 36, a configuration of a semiconductor memory device according to the third embodiment will be described. FIG. 36 is a schematic X-Y cross-sectional view for describing a part of the configuration of the semiconductor memory device according to the third embodiment.

The semiconductor memory device according to the third embodiment is basically configured similarly to the semiconductor memory device according to the first embodiment. However, the semiconductor memory device according to the third embodiment includes a memory block BLK3 instead of the memory block BLK1.

The memory block BLK3 according to the third embodiment is basically configured similarly to the memory block BLK1 according to the first embodiment. However, the memory block BLK3 according to the third embodiment includes a stacked structure SS3 instead of the stacked structure SS1.

The stacked structure SS3 according to the third embodiment is basically configured similarly to the stacked structure SS1 according to the first embodiment. However, the stacked structure SS3 according to the third embodiment includes three straight wiring portions 311 and a plurality of straight wiring portions 312. The straight wiring portions 311 extend in the X-direction and are arranged in the Y-direction. The plurality of straight wiring portions 312 are disposed in the X-direction between the two straight wiring portions 311 mutually adjacent in the Y-direction. The straight wiring portion 312 extends in a direction of −60° with respect to the X-direction, and is connected to the two straight wiring portions 311 mutually adjacent in the Y-direction. The stacked structure SS3 also includes a plurality of straight wiring portions 313 and a plurality of straight wiring portions 314. The straight wiring portion 313 extends in the X-direction, and is connected to the two straight wiring portions 312 mutually adjacent in the X-direction. The plurality of straight wiring portions 314 are disposed between the plurality of straight wiring portions 313 and the plurality of straight wiring portions 311. The straight wiring portion 314 extends in a direction of +60° with respect to the X-direction, and is connected to the straight wiring portion 311 and the straight wiring portion 313. A part of the plurality of memory structures MS1 include sides S₃₁₁ in contact with the straight wiring portions 311, sides S₃₁₂ in contact with the straight wiring portions 312, and sides S₃₁₄ in contact with the straight wiring portions 314. A part of the plurality of memory structures MS1 include sides S₃₁₂ in contact with the straight wiring portions 312, sides S₃₁₃ in contact with the straight wiring portions 313, and sides S₃₁₄ in contact with the straight wiring portions 314.

In the stacked structure SS3 according to the third embodiment, one of the above-described three straight wiring portions 311 is disposed to the position overlapping the inter-string unit insulating layer ISU viewed in the Z-direction. Therefore, a part of the plurality of conductive layers 110 included in the stacked structure SS3 are separated in the Y-direction at the parts corresponding to the straight wiring portions 311.

The semiconductor memory device according to the third embodiment may include the memory structure MS2 according to the second embodiment instead of the memory structure MS1 according to the first embodiment.

### Fourth Embodiment

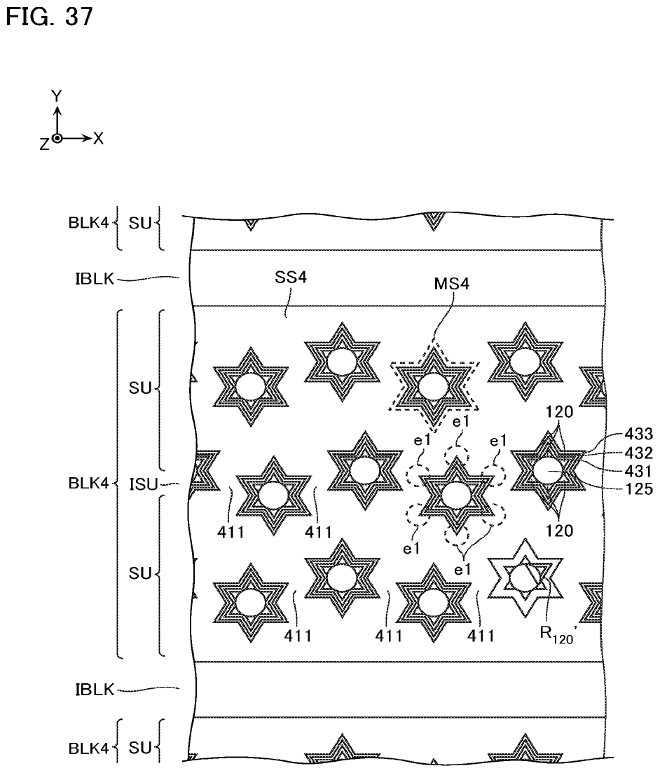

Next, with reference to FIG. 37, a configuration of a semiconductor memory device according to the fourth embodiment will be described. FIG. 37 is a schematic X-Y cross-sectional view for describing a part of the configuration of the semiconductor memory device according to the fourth embodiment.

The semiconductor memory device according to the fourth embodiment is basically configured similarly to the semiconductor memory device according to the first embodiment. However, the semiconductor memory device according to the fourth embodiment includes a memory block BLK4 instead of the memory block BLK1.

The memory block BLK4 according to the fourth embodiment is basically configured similarly to the memory block BLK1 according to the first embodiment. However, the memory block BLK4 according to the fourth embodiment includes a stacked structure SS4 and a plurality of memory structures MS4 formed in shapes of approximately six-pointed stars instead of the stacked structure SS1 and the plurality of memory structures MS1.

The memory structure MS4 according to the fourth embodiment is basically configured similarly to the memory structure MS1 according to the first embodiment. However, the memory structure MS4 is formed in not the approximately equilateral triangular prism shape but a prism shape having an approximately six-pointed star shape in the X-Y cross section. The memory structure MS4 includes an insulating layer 125 and six semiconductor layers 120. The insulating layer 125 is disposed on the center axis of the memory structure MS4. The six semiconductor layers 120 are disposed along an outer peripheral surface of the insulating layer 125 at intervals of 60°, and mutually separated. The insulating layer 125 and the six semiconductor layers 120 constitute a structure of approximately six-pointed star shape in the X-Y cross section. The memory structure MS4 includes a tunnel insulating film 431, an electric charge accumulating film 432, and a block insulating film 433 covering the outer peripheral surface of the structure having the shape of the approximately six-pointed star.

The outer peripheral surface of the memory structure MS4 includes six corner portions e1 disposed at intervals of 60°. The six corner portions e1 each extend in a direction of 0°, 60°, or 120° with respect to the X-direction, and each include mutually intersecting two straight portions. The six semiconductor layers are disposed inside respective six ranges R₁₂₀′ disposed corresponding to the six corner portions e1. The range R₁₂₀′ is a range, for example, surrounded by a straight line that extends in a direction (for example, X-direction) parallel to one of the two straight portions constituting the corner portion e1 and is circumscribed to the insulating layer 125, a straight line that extends in a direction (for example, a direction of 60° with respect to the X-direction) parallel to the other of the two straight portions constituting the corner portion e1 and is circumscribed to the insulating layer 125, and the outer peripheral surface of the insulating layer 125.

The tunnel insulating film 431, the electric charge accumulating film 432, and the block insulating film 433 are basically configured similarly to the tunnel insulating film 131, the electric charge accumulating film 132, and the block insulating film 133 according to the first embodiment. However, the tunnel insulating film 431, the electric charge accumulating film 432, and the block insulating film 433 have not the shape of the approximately equilateral triangular cylinder but the approximately six-pointed star shape.

The stacked structure SS4 is basically configured similarly to the stacked structure SS1 according to the first embodiment. However, the stacked structure SS4 according to the fourth embodiment is provided with a plurality of through-holes corresponding to the plurality of memory structures MS4. Inner peripheral surfaces of the plurality of through-holes each include twelve planar portions opposing twelve surfaces in total corresponding to the six corner portions of the memory structure MS4 formed in the six-pointed star shape. The stacked structure SS4 includes straight wiring portions 411 disposed between the two memory structures MS4 arranged mutually adjacent in the X-direction. The straight wiring portion 411 extends in the direction of 60° or 120° along the two straight portions constituting the corner portions e1 of the outer peripheral surfaces of the memory structures MS4.

The memory structure MS4 according to the fourth embodiment may include the insulating layer 225 and the six semiconductor layers 220 instead of the insulating layer 125 and the six semiconductor layers 120.

### Fifth Embodiment

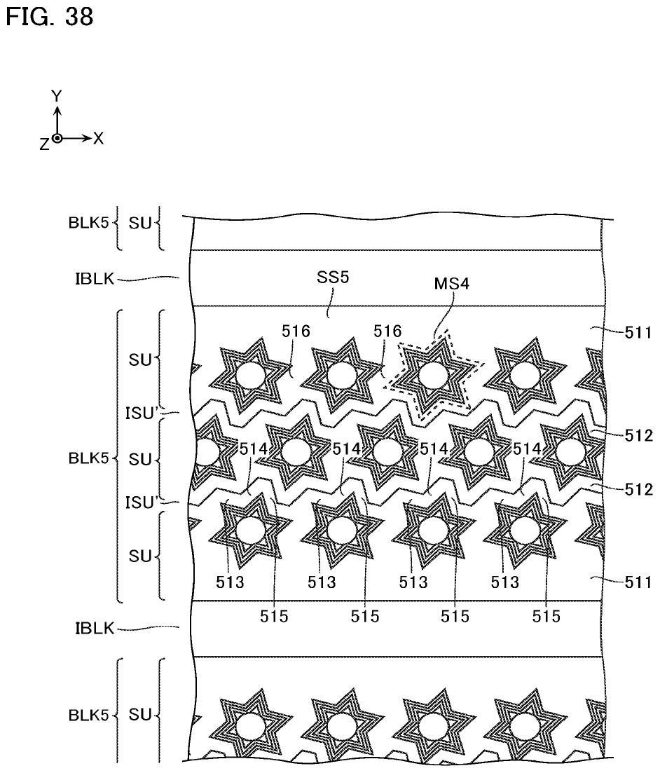

Next, with reference to FIG. 38, a configuration of a semiconductor memory device according to the fifth embodiment will be described. FIG. 38 is a schematic X-Y cross-sectional view for describing a part of the configuration of the semiconductor memory device according to the fifth embodiment.

The semiconductor memory device according to the fifth embodiment is basically configured similarly to the semiconductor memory device according to the fourth embodiment. However, the semiconductor memory device according to the fifth embodiment includes a memory block BLK5 instead of the memory block BLK4.

The memory block BLK5 according to the fifth embodiment is basically configured similarly to the memory block BLK4 according to the fourth embodiment. However, the memory block BLK5 according to the fifth embodiment includes a stacked structure SS5 instead of the stacked structure SS4.

The memory block BLK5 includes three string units SU arranged in the Y-direction. The three string units SU each include a plurality of memory structures MS4 arranged in the X-direction. Here, in the memory block BLK4 according to the fourth embodiment, the memory structure MS4 is disposed in the angle in which the apexes of the equilateral hexagon circumscribed to the memory structure MS4 are positioned at 30°, 90°, 150°, 210°, 270°, and 330° from the X-axis. Meanwhile, in the memory block BLK5 according to the fifth embodiment, the memory structure MS5 is disposed in a state of being rotated by −15°. That is, the memory block BLK5 is disposed in an angle in which the apexes of the equilateral hexagon circumscribed to the memory structure MS5 are positioned at 15°, 75°, 135°, 195°, 255°, and 315° from the X-axis.

The stacked structure SS5 includes two straight wiring portions 511 arranged in the Y-direction, and continuous straight wiring portions 512 disposed between the two string units SU mutually adjacent in the Y-direction. The continuous straight wiring portion 512 includes a plurality of straight wiring portions 513 extending in a direction of −15° from the X-direction, a plurality of straight wiring portions 514 extending in a direction of +45° from the X-direction, and a plurality of straight wiring portions 515 extending in a direction of −75° from the X-direction. The plurality of straight wiring portions 513, 514, 515 are each in contact with at least one of the two memory structures MS4 mutually adjacent in the Y-direction. The stacked structure SS5 includes a plurality of straight wiring portions 516 disposed between the two memory structures MS4 mutually adjacent in the X-direction. The plurality of straight wiring portions 516 extend in a direction of +45° from the X-direction. The plurality of straight wiring portions 516 are each in contact with the two memory structures MS4 mutually adjacent in the X-direction.

In the stacked structure SS5 according to the fifth embodiment, the continuous straight wiring portion 512 is disposed to the position overlapping an inter-string unit insulating layer ISU′ viewed in the Z-direction. That is, the inter-string unit insulating layer ISU′ according to the embodiment includes a plurality of straight portions (a part of the straight wiring portions 513, 514, 515) extending along the continuous straight wiring portion 512. Therefore, apart of the plurality of conductive layers 110 included in the stacked structure SS5 are separated in the Y-direction at the parts corresponding to the plurality of straight portions.

### Other Embodiments

The semiconductor memory devices according to the first embodiment to the fifth embodiment are described above. However, these configurations are merely examples, and the specific configuration and the like are adjustable as necessary.

For example, in the memory structures MS1, MS2, and MS4 according to the first embodiment to the fifth embodiment, the tunnel insulating films 131, 431, the electric charge accumulating films 132, 432, and the block insulating films 133, 433 are continuously formed along the outer peripheral surfaces of the memory structures MS1, MS2, and MS4. However, at least apart of them may be separated into a plurality of parts together with the semiconductor layers 120.

For example, the memory structures MS1, MS2 according to the first embodiment to the third embodiment are formed in the approximately equilateral triangular prism shape. However, this configuration is merely an example, and the specific configuration is adjustable as necessary. For example, the memory structures MS1, MS2 may have columnar shapes of an equilateral n-polygonal prism shape (n is a natural number of three or more) other than the equilateral triangular prism. Also in this case, n semiconductor layers mutually separated in the X-Y cross section may be disposed corresponding to a range of the equilateral n-polygon that passes through points on an outer peripheral surface of a configuration corresponding to the insulating layer 125 and is circumscribed to the configuration in the X-Y cross section. When focusing on the two memory structures mutually adjacent in the X-Y cross section, the equilateral n-polygons corresponding to the two memory structures may include mutually parallel two sides. The configuration corresponding to the stacked structures SS1, SS3 may include a straight wiring portion that is disposed between the two sides and extends in a direction parallel to the two sides.

For example, the memory structure MS4 according to the fourth embodiment and the fifth embodiment is formed in the approximately six-pointed star shape. However, this configuration is merely an example, and the specific configuration is adjustable as necessary. For example, the memory structure MS4 may include mutually separated n semiconductor layers disposed at intervals of 360°/n (n is a natural number of three or more) along an outer peripheral surface of a configuration corresponding to the insulating layer 125. The outer peripheral surface of the memory structure MS4 may include n corner portions disposed at intervals of 360°/n. The n corner portions may each include mutually intersecting two straight portions. The n semiconductor layers may be each disposed inside a range surrounded by the two straight lines and the outer peripheral surface of the configuration corresponding to the insulating layer 125. The two straight lines extend in directions parallel to the corresponding two straight portions, and are circumscribed to the configuration corresponding to the insulating layer 125. When focusing on the two memory structures mutually adjacent in the X-Y cross section, any straight portion included in the outer peripheral surface of the one memory structure may be parallel to any straight portion included in the outer peripheral surface of the other memory structure. The configuration corresponding to the stacked structures SS4, SS5 may include a straight wiring portion that is disposed between the two straight portions and extends in a direction parallel to the two straight portions.

[Others]

While certain embodiments have been described, these embodiments have been presented by way of example only, and are not intended to limit the scope of the inventions. Indeed, the novel methods and systems described herein may be embodied in a variety of other forms: furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a substrate;
a first conductive layer disposed to be separated from the substrate in a first direction intersecting with a surface of the substrate; and
a memory structure having an outer peripheral surface surrounded by the first conductive layer in a first plane, the first plane being perpendicular to the first direction and including a part of the first conductive layer, wherein
the memory structure includes:
a first insulating layer;
n (n is a natural number of three or more) first semiconductor layers disposed between the first conductive layer and the first insulating layer, then first semiconductor layers being mutually separated in the first plane; and
a gate insulating film disposed between the first conductive layer and the n first semiconductor layers in the first plane, wherein
when an equilateral n-polygon passes through points on an outer peripheral surface of the first insulating layer and is circumscribed to the first insulating layer, the points have a shortest distance to the first conductive layer, and a range of the equilateral n-polygon is defined as a first range, in the first plane,
the n first semiconductor layers are disposed inside the first range.

2. The semiconductor memory device according to claim 1, further comprising
n bit lines disposed corresponding to the n first semiconductor layers, wherein
the n bit lines extend in a second direction intersecting with the first direction,
the n bit lines are arranged in a third direction intersecting with the first direction and the second direction, and
the n bit lines are electrically connected to the n first semiconductor layers.

3. The semiconductor memory device according to claim 1, further comprising
n impurity regions disposed at one end portions in the first direction of the n first semiconductor layers.

4. The semiconductor memory device according to claim 1, further comprising
second semiconductor layers disposed at other end portions in the first direction of the n first semiconductor layers.

5. The semiconductor memory device according to claim 1, comprising
a plurality of the memory structures having outer peripheral surfaces surrounded by the first conductive layer in the first plane, wherein
the first conductive layer includes a straight wiring portion disposed between two memory structures among the plurality of memory structures, the straight wiring portion extends along two sides constituting the equilateral n-polygons corresponding to the first ranges of the two memory structures, and the straight wiring portion is in contact with the two memory structures.

6. The semiconductor memory device according to claim 5, further comprising:
a second conductive layer and a third conductive layer disposed to be separated from the substrate and the first conductive layer in the first direction; and
a second insulating layer disposed between the second conductive layer and the third conductive layer, wherein
the second conductive layer and the third conductive layer are arranged in a second direction intersecting with the first direction, and
outer peripheral surfaces of the plurality of memory structures oppose at least one of the second conductive layer and the third conductive layer in a second plane, the second plane is perpendicular to the first direction and partially includes the second conductive layer and the third conductive layer.

7. The semiconductor memory device according to claim 6, wherein
the first conductive layer includes a plurality of first straight wiring portions extending in a third direction that intersects with the first direction and the second direction, the plurality of first straight wiring portions are arranged in the second direction, and
the second insulating layer is disposed at a position without overlapping any of the plurality of first straight wiring portions viewed in the first direction.

8. The semiconductor memory device according to claim 6, wherein
the first conductive layer includes a plurality of first straight wiring portions extending in a third direction that intersects with the first direction and the second direction, the plurality of first straight wiring portions are arranged in the second direction, and
the second insulating layer is disposed at a position overlapping any of the plurality of first straight wiring portions viewed in the first direction.

9. A semiconductor memory device comprising:
a substrate;
a first conductive layer disposed to be separated from the substrate in a first direction intersecting with a surface of the substrate; and
a plurality of memory structures having outer peripheral surfaces surrounded by the first conductive layer in a first plane, the first plane being perpendicular to the first direction and including a part of the first conductive layer, wherein
the memory structure includes:
a first insulating layer;
n (n is a natural number of three or more) first semiconductor layers each disposed between the first conductive layer and the first insulating layer, then first semiconductor layers being mutually separated in the first plane; and
a gate insulating film disposed between the first conductive layer and the n first semiconductor layers in the first plane,
an outer peripheral surface of the memory structure includes n corner portions disposed corresponding to the n first semiconductor layers, and the n corner portions each include two straight portions extending along mutually intersecting directions in the first plane, and
the first conductive layer includes a straight wiring portion disposed between two memory structures among the plurality of memory structures, the straight wiring portion extends along mutually parallel two straight portions included in outer peripheral surfaces of the two memory structures, and the straight wiring portion is in contact with the two memory structures in the first plane.

10. The semiconductor memory device according to claim 9, further comprising
n bit lines disposed corresponding to the n first semiconductor layers, wherein
the n bit lines extend in a second direction intersecting with the first direction,
the n bit lines are arranged in a third direction intersecting with the first direction and the second direction, and
the n bit lines are electrically connected to the n first semiconductor layers.

11. The semiconductor memory device according to claim 9, further comprising
n impurity regions disposed at one end portions in the first direction of the n first semiconductor layers.

12. The semiconductor memory device according to claim 9, further comprising
second semiconductor layers disposed at other end portions in the first direction of the n first semiconductor layers.

13. The semiconductor memory device according to claim 9, wherein
the n first semiconductor layers are each disposed inside a range surrounded by two straight lines and an outer peripheral surface of the first insulating layer, and the two straight lines extend in directions parallel to the two straight portions of the corner portion and are circumscribed to the first insulating layer.

14. The semiconductor memory device according to claim 9, further comprising:
a second conductive layer and a third conductive layer disposed to be separated from the substrate and the first conductive layer in the first direction; and
a second insulating layer disposed between the second conductive layer and the third conductive layer, wherein
the second conductive layer and the third conductive layer are arranged in a second direction intersecting with the first direction, and
outer peripheral surfaces of the plurality of memory structures oppose at least one of the second conductive layer and the third conductive layer in a second plane, the second plane is perpendicular to the first direction and partially includes the second conductive layer and the third conductive layer.

15. The semiconductor memory device according to claim 14, wherein
the first conductive layer includes a plurality of first straight wiring portions extending in a third direction that intersects with the first direction and the second direction, the plurality of first straight wiring portions are arranged in the second direction, and
the second insulating layer is disposed at a position without overlapping any of the plurality of first straight wiring portions viewed in the first direction.

16. The semiconductor memory device according to claim 14, wherein
the first conductive layer includes a plurality of first straight wiring portions extending in a third direction that intersects with the first direction and the second direction, the plurality of first straight wiring portions are arranged in the second direction, and
the second insulating layer is disposed at a position overlapping any of the plurality of first straight wiring portions viewed in the first direction.

17. The semiconductor memory device according to claim 14, wherein
in the second plane, the second insulating layer includes:
a plurality of first parts extending in a fourth direction that intersects with the first direction and the second direction; and
a plurality of second parts extending in a fifth direction that intersects with the first direction, the second direction, and the fourth direction.
